(19) United States
(12) Patent Application Publication
(10) Pub. No.: US 2026/0039083 A1
(43) Pub. Date: Feb. 5, 2026

(54) LIGHT EMITTING MODULE

(71) Applicant: SEOUL SEMICONDUCTOR CO., LTD., Ansan-si (KR)

(72) Inventors: Myungjin KIM, Ansan-si (KR); YeongSik JEONG, Ansan-si (KR)

(73) Assignee: SEOUL SEMICONDUCTOR CO., LTD., Ansan-si (KR)

(21) Appl. No.: 19/280,608

(22) Filed: Jul. 25, 2025

Related U.S. Application Data
(60) Provisional application No. 63/678,812, filed on Aug. 2, 2024.

(51) Int. Cl. H01S 5/02255; H01S 5/02208; H01S 5/02315

(52) U.S. Cl. CPC H01S 5/02255; H01S 5/02208; H01S 5/02315

(57) ABSTRACT

A light emitting apparatus includes a substrate; a light emitting device disposed on the substrate and configured to generate light; a second light-transmitting layer disposed on the substrate so that light generated from the light emitting device is transmitted therethrough; a first reflective layer disposed between the substrate and the light emitting device; and a second reflective layer disposed on the substrate and configured to reflect light toward the second light-transmitting layer, wherein the second reflective layer includes 20 wt % to 70 wt % of aluminum and 10 wt % to 60 wt % of oxygen.

### CROSS-REFERENCE TO RELATED APPLICATIONS

The present application claims the benefit of priority to U.S. Provisional Application No. 63/678,812, filed Aug. 2, 2024, the disclosure of which is incorporated by reference herein in its entirety.

### FIELD

Various implementations of the disclosed technology relate to a light emitting apparatus, more particularly to a light emitting module including a light emitting device.

### BACKGROUND

A light emitting diode is a semiconductor element that emits light generated by recombination of electrons and holes, and is used in various fields such as displays, automobile lamps, and general lighting in recent times. The light emitting diode is applied in various fields such as automobile lamps and display devices, because a lifespan is long, the power consumption is low, and response speed is fast.

However, in order to enhance the light extraction efficiency of light emitting diodes, it is necessary to develop technologies capable of efficiently reflecting light.

### SUMMARY

Embodiments of the disclosed technology may provide a light emitting module capable of emitting light by efficiently reflecting light.

Embodiments of the disclosed technology may provide a light emitting module capable of efficiently emitting light by increasing a light extraction efficiency of the light emitting module.

Embodiments of the disclosed technology may provide a light emitting module capable of efficiently emitting light by improving a light extraction efficiency using a difference in refractive index.

Embodiments of the disclosed technology may provide a light emitting module having high reliability by protecting a light emitting device from an external environment.

Embodiments of the disclosed technology may provide a light emitting module with improved reliability by delaying moisture penetration through increasing a length of a moisture penetration path.

Embodiments of the disclosed technology may provide a light emitting module with improved reliability by increasing a heat dissipation efficiency through efficiently emitting heat.

Embodiments of the disclosed technology may provide a light emitting module with an improved thermal reliability by alleviating thermal shock through reducing a thermal expansion coefficient.

In accordance with one embodiment of the disclosed technology, there may be provided a light emitting apparatus, including: a substrate; a light emitting device disposed on the substrate and configured to generate light; a second light-transmitting layer disposed on the substrate so that light emitted from the light emitting device is transmitted therethrough; a first reflective layer disposed between the substrate and the light emitting device; and a second reflective layer disposed on the substrate and configured to reflect light toward the second light-transmitting layer, wherein the second reflective layer includes 20 wt % to 70 wt % of aluminum, 10 wt % to 60 wt % of oxygen, and a remainder.

Further, there may be provided the light emitting apparatus in which the remainder includes silicon and carbon, and a content of the carbon is greater than a content of the silicon. Further, there may be provided the light emitting apparatus in which the substrate includes: a base on which the light emitting device is disposed, the first reflective layer, and the second reflective layer; and a sidewall extending upward from the base at an edge of the base, and the second reflective layer is disposed between the sidewall and the light emitting device.

Further, there may be provided the light emitting apparatus in which the second reflective layer is formed in plural, and the plurality of second reflective layers are disposed to be spaced apart from each other along an inner region of the sidewall.

Further, there may be provided the light emitting apparatus further comprising a plurality of protrusions formed in an inner region of the sidewall.

Further, there may be provided the light emitting apparatus in which a thickness of the second reflective layer increases toward the sidewall.

Further, there may be provided the light emitting apparatus in which a surface of the second reflective layer is formed to be concave downward.

Further, there may be provided the light emitting apparatus in which a thickness of the second reflective layer decreases toward the sidewall.

Further, there may be provided the light emitting apparatus further including: a protective device disposed on the base so as to be disposed between the sidewall and the light emitting device, wherein the second reflective layer covers at least one region of the protective device.

Further, there may be provided the light emitting apparatus in which the second reflective layer and the light emitting device are spaced apart from each other.

Further, there may be provided the light emitting apparatus in which the light emitting device is disposed inside the first reflective layer when viewed from one region.

Further, there may be provided the light emitting apparatus in which the second reflective layer includes at least one of alumina (Al₂O₃) or barium sulfate (BaSO₄).

Further, there may be provided the light emitting apparatus in which the second reflective layer further includes one or more fillers for refracting light, and an average of lengths of long sides of the one or more fillers is 100 nm to 2 μm.

Further, there may be provided the light emitting apparatus further including: a third light-transmitting layer disposed on at least one region of the light emitting device.

Further, there may be provided the light emitting apparatus in which the first reflective layer and the second reflective layer are formed to differ from each other in at least one of reflectance, thermal conductivity, or thermal expansion coefficient.

Further, there may be provided the light emitting apparatus in which the first reflective layer is formed in plurality and spaced apart from each other in a horizontal direction, the light emitting device is disposed above one of the plurality of first reflective layers spaced apart from each other in the horizontal direction, and the second reflective layer is disposed between the plurality of first reflective layers.

Further, there may be provided a light emitting apparatus including: a substrate; a light emitting device disposed on the substrate; a second light-transmitting layer disposed on the substrate so that light generated from the light emitting device is transmitted therethrough; a first reflective layer disposed between the substrate and the light emitting device; and a second reflective layer disposed on the substrate and configured to reflect light toward the second light-transmitting layer, wherein the light emitting device includes: a device substrate stacked on the first reflective layer; a first semiconductor layer disposed on the device substrate; an active layer disposed on the first semiconductor layer; and a second semiconductor layer disposed on the active layer.

Further, there may be provided the light emitting apparatus in which the substrate includes: a base on which the light emitting device disposed thereon, the first reflective layer, and the second reflective layer; and a sidewall extending upward from the base at an edge region of the base, wherein the first reflective layer is disposed on a region where at least one region thereof faces the light emitting device and another region opposite the at least one region faces the sidewall, and wherein the at least one region of the first reflective layer is disposed below a region between the device substrate and the first conductive semiconductor layer.

Further, there may be provided a light emitting apparatus including: a substrate; a light emitting device disposed on the substrate; a second light-transmitting layer disposed on the substrate so that light generated from the light emitting device is transmitted therethrough; a first reflective layer having at least one region disposed between the substrate and the light emitting device; and a second reflective layer disposed on the substrate and configured to reflect light toward the second light-transmitting layer, wherein the light emitting device includes: a first semiconductor layer electrically disposed on the substrate; an active layer disposed on the first semiconductor layer; a second semiconductor layer disposed on the active layer and electrically connected to the substrate; and a first light-transmitting layer disposed on the second semiconductor layer.

Further, there may be provided a light emitting apparatus in which a region between the second semiconductor layer and the first light-transmitting layer is disposed below a surface of the second reflective layer.

A light emitting apparatus of an embodiment of the disclosed technology has an effect in that a surface light emission effect may be improved since light may be efficiently reflected.

A light emitting apparatus of an embodiment of the disclosed technology has an effect in that light in a UV wavelength band may be efficiently reflected.

Embodiments of the disclosed technology may efficiently emit light by increasing a light extraction efficiency of the light emitting apparatus.

Embodiments of the disclosed technology may efficiently emit light by improving a light extraction efficiency using a difference in refractive index.

Embodiments of the disclosed technology may improve a reliability by protecting a light emitting device from an external environment.

Embodiments of the disclosed technology may improve reliability by delaying moisture penetration through increasing a length of a moisture penetration path.

Embodiments of the disclosed technology may improve reliability by increasing heat dissipation efficiency through efficiently emitting heat.

Embodiments of the disclosed technology may improve a thermal reliability by alleviating thermal shock through reducing a thermal expansion coefficient.

### BRIEF DESCRIPTION OF DRAWINGS

FIG. 1 is a diagram illustrating a light emitting module according to a first embodiment of the disclosed technology.

FIG. 2 is a diagram illustrating, as seen from above, a state in which a second light-transmitting layer and a first reflective layer of the light emitting module according to the first embodiment of the disclosed technology are removed.

FIG. 3 is a diagram illustrating a state in which a second reflective layer of the light emitting module in FIG. 2 covers a protective device.

FIG. 4 is a diagram illustrating a state in which the second reflective layer of the light emitting module in FIG. 2 is formed in plural.

FIG. 5 is a diagram illustrating a state in which the second reflective layer of the light emitting module in FIG. 2 is disposed along a sidewall.

FIG. 6 is a diagram illustrating a state in which the second reflective layer of the light emitting module in FIG. 2 is extended along an inner peripheral surface of the sidewall.

FIG. 7 is a graph illustrating a reflectance of the second reflective layer of the light emitting module in FIG. 1 for each wavelength band.

FIG. 8 is a diagram illustrating a light emitting module according to a second embodiment of the disclosed technology.

FIG. 9 is a diagram illustrating a light emitting module according to a third embodiment of the disclosed technology.

FIG. 10 is a diagram illustrating a light emitting module according to a fourth embodiment of the disclosed technology.

FIG. 11 is a diagram illustrating a light emitting module according to a fifth embodiment of the disclosed technology.

FIG. 12 is a diagram illustrating a light emitting module according to a sixth embodiment of the disclosed technology.

FIG. 13 is a diagram illustrating a first example of the light emitting module according to a seventh embodiment of the disclosed technology.

FIG. 14 is a diagram illustrating a second example of the light emitting module according to the seventh embodiment of the disclosed technology.

FIG. 15 is a diagram illustrating a third example of the light emitting module according to the seventh embodiment of the disclosed technology.

FIG. 16 is a diagram illustrating a fourth example of the light emitting module according to the seventh embodiment of the disclosed technology.

FIG. 17 is a diagram illustrating a fifth example of the light emitting module according to the seventh embodiment of the disclosed technology.

FIG. 18 is a diagram illustrating a first example of the light emitting module according to an eighth embodiment of the disclosed technology.

FIG. 19 is a diagram illustrating a second example of the light emitting module according to the eighth embodiment of the disclosed technology.

FIG. 20 is a diagram illustrating a third example of the light emitting module according to the eighth embodiment of the disclosed technology.

FIG. 21 is a diagram illustrating a fourth example of the light emitting module according to the eighth embodiment of the disclosed technology.

FIG. 22 is a diagram illustrating a fifth example of the light emitting module according to the eighth embodiment of the disclosed technology.

### DETAILED DESCRIPTION

In the following description, for the purposes of explanation, numerous specific details are set forth in order to provide thorough understanding of various exemplary embodiments or implementations of the present disclosure. As used herein, “embodiments” and “implementations” are interchangeable terms for non-limiting examples of devices or methods employing one or more of the inventive concepts disclosed herein. It will be apparent, however, that various exemplary embodiments may be practiced without these specific details or with one or more equivalent arrangements. In other instances, well-known structures and devices are shown in block diagram form in order to avoid unnecessarily obscuring various exemplary embodiments. Further, various exemplary embodiments may be different, but do not have to be exclusive. For example, specific shapes, configurations, and characteristics of an exemplary embodiment may be used or implemented in another exemplary embodiment without departing from the inventive concepts.

Unless otherwise specified, the illustrated exemplary embodiments are to be understood as providing exemplary features of varying detail of some ways in which the inventive concepts may be implemented in practice. Therefore, unless otherwise specified, the features, components, modules, layers, films, panels, regions, and/or aspects (hereinafter individually or collectively referred to as “elements”) of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, and property of the elements, unless specified. Further, in the accompanying drawings, the size and relative sizes of elements may be exaggerated for clarity and/or descriptive purposes. When an exemplary embodiment is implemented differently, a specific process order may be performed differently from the described order. For example, two consecutively described processes may be performed substantially at the same time or performed in an order opposite the described order. In addition, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the DR1-axis, the DR2-axis, and the DR3-axis are not limited to three axes of a rectangular coordinate system, such as the x, y, and z-axes, and may be interpreted in a broader sense. For example, the DR1-axis, the DR2-axis, and the DR3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” and the like may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (for example, as in “sidewall”), and the like, may be used herein for descriptive purposes, and, thereby, to describe one element's relationship to other element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (for example, rotated 90 degrees or at other orientations), and, as such, the spatially relative descriptors used herein may likewise interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various exemplary embodiments are described herein with reference to sectional and/or exploded illustrations that are schematic illustrations of idealized exemplary embodiments and/or intermediate structures. As such, variations from the shapes of the illustrations as a result, for example, of manufacturing techniques and/or tolerances, are to be expected. Thus, exemplary embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some exemplary embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (for example, microcode) to perform various functions discussed herein and may optionally be driven by firmware and/or software. It is also contemplated that each block, unit, and/or module may be implemented by dedicated hardware, or as a combination of dedicated hardware to perform some functions and a processor (for example, one or more programmed microprocessors and associated circuitry) to perform other functions.

Also, each block, unit, and/or module of some exemplary embodiments may be physically separated into two or more interacting and discrete blocks, units, and/or modules without departing from the scope of the inventive concepts. Further, the blocks, units, and/or modules of some exemplary embodiments may be physically combined into more complex blocks, units, and/or modules without departing from the scope of the inventive concepts.

Unless otherwise defined, all terms (including technical and scientific terms) used herein have the same meaning as commonly understood by one of ordinary skill in the art to which this disclosure pertains. Terms, such as those defined in commonly used dictionaries, should be interpreted as having a meaning that is consistent with their meaning in the context of the relevant art and should not be interpreted in an idealized or overly formal sense, unless expressly so defined herein.

Hereinafter, a specific configuration of a light emitting module 1 according to a first embodiment of the disclosed technology will be described with reference to the drawings.

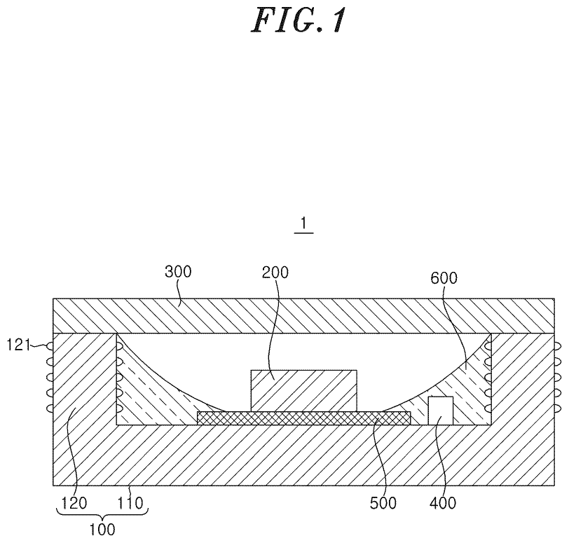

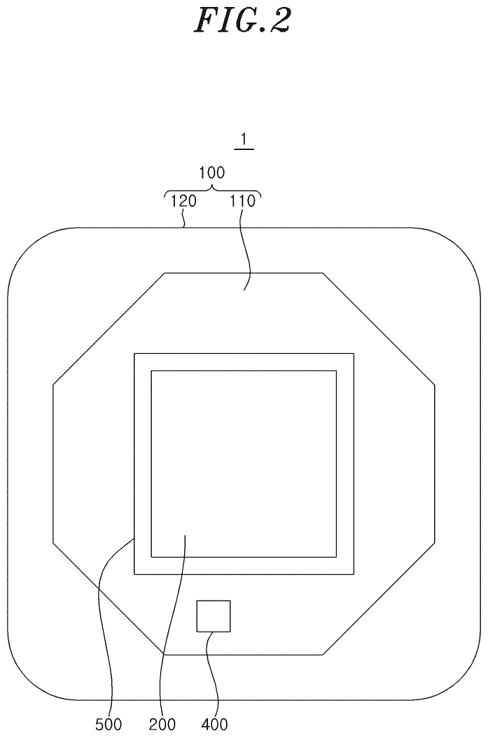

With reference to FIGS. 1 and 2, a light emitting module 1 according to a first embodiment of the disclosed technology may be capable of emitting light by receiving power from an outside. The light emitting module 1 may include a substrate 100, a light emitting device 200, a second light-transmitting layer 300, a protective device 400, a first reflective layer 500, and a second reflective layer 600.

At least one region of the substrate 100 may be disposed with the light emitting device 200, the second light-transmitting layer 300, the protective device 400, the first reflective layer 500, and the second reflective layer 600. For example, the substrate 100 may be a printed circuit board (PCB). In addition, the substrate 100 may include an alloy composed of one or more of Cu, Zn, Au, Ni, Al, Mg, Cd, Be, W, Mo, Si, Ag, or Fe, or some combination thereof. However, this is merely an example, and the substrate 100 may also include one or more of FR1, CEM-1, or FR-4. Here, FR1 is a material in which copper foil and laminate paper are stacked, and CEM-1 is a material in which copper foil, glass fiber woven fabric, laminate paper, and glass fiber woven fabric are sequentially stacked. In addition, FR-4 is a material in which copper foil and glass fiber woven fabric or glass fiber fabric are stacked. In addition, the substrate 100 may include ceramic, such as alumina (Al₂O₃), aluminum nitride (AlN), or zirconia toughened alumina (ZTA). In addition, the substrate 100 may include abase 110 and a sidewall 120.

At least one region of the base 110 may be disposed with the light emitting device 200, the protective device 400, the first reflective layer 500, and the second reflective layer 600. At least one region of the base 110 may be disposed with a circuit wiring electrically connectable to an external power source. In other words, through the base 110, the light emitting device 200 and the protective device 400 may be electrically connected to the external power source. In addition, the base 110 may reflect a part of light generated from the light emitting device 200. A size of the base 110 may be larger than the light emitting device 200, and may protect the light emitting device 200 from external impact.

The sidewall 120 may extend upward from an edge of the base 110, and may provide an accommodation space for accommodating the light emitting device 200 therein. The sidewall 120 may extend so as to surround at least one region of the light emitting device 200. The accommodation space may be filled with air, a material having a low refractive index, or a molding layer. A height of the sidewall 120 may be formed to be equal to or greater than a height of the light emitting device 200, so that the light emitting device 200 may be protected from external impact. The sidewall 120 may reflect light generated from the light emitting device 200. In addition, in one region of the sidewall 120, one region of the second reflective layer 600 may be disposed or contacted.

A protrusion 121 may be formed on the sidewall 120. The protrusion 121 may be formed on one or more of an inner peripheral surface or an outer peripheral surface of the sidewall 120. By the protrusion 121, at least one region of the inner peripheral surface and the outer peripheral surface of the sidewall may be formed to be irregular. At least some of a plurality of the protrusions 121 may be formed in different shapes. By the plurality of the protrusions 121, the sidewall 120 may more effectively reflect light. In addition, by the plurality of the protrusions 121, an adhesive force between the second reflective layer 600 and the sidewall 120 may be increased, so that separation of the second reflective layer 600 from the sidewall 120 due to a temperature change, or the like may be reduced and reliability may be improved. Accordingly, the surface area of the sidewall 120 may be greater than the area of its vertical surface. However, a protrusion 121 may not be formed on the sidewall 120, and it should be understood that the disclosed technology is not limited thereto.

The light emitting device 200 may generate light. For example, the light emitting device 200 may be an element that converts electric energy into light, such as a light emitting diode, a laser diode, or an organic light emitting diode. In this case, the light emitting device 200 may generate UVC (200 nm to 280 nm), UVB (280 nm to 315 nm), UVA (315 nm to 420 nm), blue light, green light, yellow light, red light, infrared light, and the like. The light emitting device 200 may be electrically connected to an electric circuit of the substrate 100 and may generate light by receiving electricity from the outside through the electric circuit. As an example, the light emitting device 200 may be a light emitting structure including the substrate and a plurality of layers grown on the substrate. The light emitting structure may include a first conductive semiconductor layer, an active layer, and a second conductive semiconductor layer. The first conductive semiconductor layer may include a phosphide-based or a nitride-based semiconductor, such as (Al, Ga, In)P or (Al, Ga, In)N. The first conductive semiconductor layer may be doped as n-type, and may include at least one impurity such as Si, C, Ge, Sn, Te, or Pb. However, the first conductive semiconductor layer is not limited thereto and may also be doped as p-type by including a p-type dopant. The active layer is a light emitting layer formed between the first conductive semiconductor layer and the second conductive semiconductor layer, and may include a phosphide-based or nitride-based semiconductor such as (Al, Ga, In)P or (Al, Ga, In)N, and may include a quantum well structure (QW) including two barrier layers and at least one well layer. In addition, the active layer may adjust a wavelength of emitted light by adjusting a composition ratio forming the well layer. The second conductive semiconductor layer may be a semiconductor layer formed on the active layer. The second conductive semiconductor layer may include a phosphide-based or nitride-based semiconductor such as (Al, Ga, In)P or (Al, Ga, In)N, and the second conductive semiconductor layer may be doped with a conductive type opposite to a conductive type of the first conductive semiconductor layer. For example, the second conductive semiconductor layer may be doped with a p-type material by including an impurity such as Mg. The second conductive semiconductor layer may be formed as a single layer having a composition such as p-GaN, but is not limited thereto, and may further include an AlGaN layer inside. The light emitting device 200 may include a lower contact layer, an insulating layer, a P-electrode pad, and an N-electrode pad.

A length in a horizontal direction of the light emitting device 200 may be smaller than a length in a horizontal direction of the first reflective layer 500. In other words, the light emitting device 200 may be disposed inside the first reflective layer 500 when viewed from the upper side to the lower side. The light emitting device 200 may be configured as a flip chip, a lateral chip, or a vertical chip.

The second light-transmitting layer 300 may be disposed on the substrate 100 so that light generated from the light emitting device 200 is transmitted. An edge of the second light-transmitting layer 300 may be disposed on the sidewall 120, and may cover an accommodation space of the sidewall 120. The second light-transmitting layer 300 may be glass. In addition, a composition of the second light-transmitting layer 300 may be quartz, borosilicate glass, soda-lime glass, silicone resin, epoxy resin, PPA, or the like. Such a second light-transmitting layer 300 may transmit light reflected from one of the second reflective layer 600, the first reflective layer 500, or the substrate 100, or may reflect light toward one of the second reflective layer 600, the first reflective layer 500, or the substrate 100. For example, light generated from the light emitting device 200 may be reflected toward the second reflective layer 600 at the second light-transmitting layer 300, then reflected again from the second reflective layer 600 toward the second light-transmitting layer 300, and may pass through the second light-transmitting layer 300 to be emitted to the outside. The second light-transmitting layer 300 may protect the light emitting device 200 from external moisture or dust, thereby improving reliability. The width of the second light-transmitting layer 300 may be 101% to 130% of the width of the first reflective layer 500. This can enhance upward light reflection efficiency and improve a light extraction efficiency. In this case, the maximum thickness of the first reflective layer 500 may be 2% to 20% of the maximum thickness of the second reflective layer 600, thereby reducing design complexity. Additionally, the second reflective layer 600 may become thicker toward the sidewall 120. The minimum thickness of the second reflective layer 600 may be less than the maximum thickness of the first reflective layer 500, which also contributes to lowering design complexity.

The protective device 400 may be electrically connected to the base 110, and may be electrically connected to the light emitting device 200 through the base 110, so that the light emitting device 200 may be protected from electrical shocks such as ESD or surge. For example, the protective device 400 may be a device such as a Zener diode, a TVS diode, a varistor, or an inverter, but is not limited thereto. The protective device 400 may be disposed on the base 110 to be spaced apart from the first reflective layer 500 and the light emitting device 200 in a horizontal direction. In addition, the protective device 400 may be covered by the second reflective layer 600, and may not be exposed to the outside. In other words, light from the light emitting device 200 may not be absorbed by the protective device 400, and may be reflected by the second reflective layer 600, so that light extraction efficiency of the light emitting module 1 may be improved. The height of the second reflective layer 600 adjacent to the side of the protective device 400 may be 110% to 130% of the height of the protective device 400. This can reduce light absorption in the protective device 400, thereby increasing the light extraction efficiency.

The first reflective layer 500 may be disposed between the substrate 100 and the light emitting device 200, and may reflect light generated from the light emitting device 200. When viewed from the upper side to the lower side, the first reflective layer 500 may be formed to be larger than the light emitting device 200. In other words, a length in a horizontal direction of the first reflective layer 500 may be formed to be larger than a length in a horizontal direction of the light emitting device 200, so that the first reflective layer 500 may reflect a portion of light emitted from the light emitting device 200 toward the bottom to an upper surface of the light emitting module 1, thereby increasing an amount of light. The light emitting device 200 may have a length of 15% to 45% of the width of the first reflective layer 500. Due to the first reflective layer 500, light directed downward can be reflected upward, thereby improving the light extraction efficiency. Additionally, the width of the first reflective layer 500 may be 80% to 120% of the distance to the sidewall 120. This may allow light reflected from the first reflective layer 500 to be further reflected toward the sidewall 120 and the upper surface, thus enhancing the light extraction efficiency.

The first reflective layer 500 and the second reflective layer 600 may be formed to differ from each other in at least one of a reflectance, thermal conductivity, or a thermal expansion coefficient. The thermal conductivity of the first reflective layer 500 may be greater than thermal conductivity of the second reflective layer 600. Since the first reflective layer 500 may be in contact with the light emitting device 200 and may efficiently dissipate heat of the light emitting device 200, heat dissipation of the light emitting device 200 may be transferred to the outside, and thermal resistance may be reduced, thereby improving the reliability of the light emitting module 1. The length of the contact surface between the first reflective layer 500 and the base 110 may be larger than that between the second reflective layer 600 and the base 110. This may allow heat from the light emitting device 200 to be efficiently discharged downward through the base 110, thereby improving reliability. Additionally, the contact area between the light emitting device 200 and the first reflective layer 500 may be larger than that between the light emitting device 200 and the second reflective layer 600. As a result, heat from the light emitting device 200 may be transferred externally, further enhancing the reliability.

The reflectance of the first reflective layer 500 may be smaller than the reflectance of the second reflective layer 600. One region of the second reflective layer 600 having low reflectance may be covered by the first reflective layer 500 having high reflectance, so that light extraction efficiency may be improved. In addition, a thermal expansion coefficient of the first reflective layer 500 may be smaller than a thermal expansion coefficient of the second reflective layer 600, and a thermal shock may be alleviated so that the light emitting device 200 is not detached from the base 110. The surface area of the second reflective layer 600 may be larger than that of the first reflective layer 500. The surface area of the second reflective layer 600 may be 105% to 125% of the surface area of the first reflective layer 500. The increased surface area of the second reflective layer 600 can enhance the light extraction efficiency.

The second reflective layer 600 may be supported on the substrate 100 and reflect light toward the second light-transmitting layer 300, thereby increasing the light extraction efficiency and the amount of light of the light emitting module 1. In addition, the second reflective layer 600 may include a plurality of fillers in an organic compound binder such as silicone or epoxy, so as to refract light incident into the inside toward the second light-transmitting layer 300. An average of lengths of long sides of the plurality of fillers may be 100 nm to 2 μm. In addition, the fillers of the second reflective layer 600 may include 20 wt % to 70 wt % of aluminum, 10 wt % to 60 wt % of oxygen, and a remainder. In other words, an arbitrary unit region of the second reflective layer may include 20 wt % to 70 wt % of aluminum, 10 wt % to 60 wt % of oxygen, and the remainder. The remainder may include silicon and carbon. The content of carbon may be formed to be greater than the content of silicon. In addition, the second reflective layer 600 may include at least one of alumina (Al₂O₃) and barium sulfate (BaSO₄). The angle formed between the second reflective layer 600 and the second light-transmitting layer 300 may be smaller than the angle formed between the sidewall 120 and the second light-transmitting layer 300. The angle at the junction where the second reflective layer 600 meets the second light-transmitting layer 300 may be acute. For example, the angle at the junction where the second reflective layer 600 meets the second light-transmitting layer 300 may range from 50° to 80°. The angle between the sidewall 120 and the second light-transmitting layer 300 may range from 80° to 95°. This configuration may allow light to be reflected from the second reflective layer 600 to the second light-transmitting layer 300, thereby increasing the light extraction efficiency.

Meanwhile, when the second light-transmitting layer 300 is removed and the second reflective layer 600 is provided, an emission angle of the light emitting device 200 may be formed to be narrower than an emission angle of the light emitting device 200 when the second light-transmitting layer 300 and the second reflective layer 600 are removed. In other words, by disposing the second reflective layer 600, the light concentrating efficiency (the light intensity concentration) of the light emitting device 200 may be further improved, and a sterilization effect and a curing effect may be improved. A difference in the emission angle before and after removal of the second light-transmitting layer 300 and the second reflective layer 600 may range from 10° to 30°.

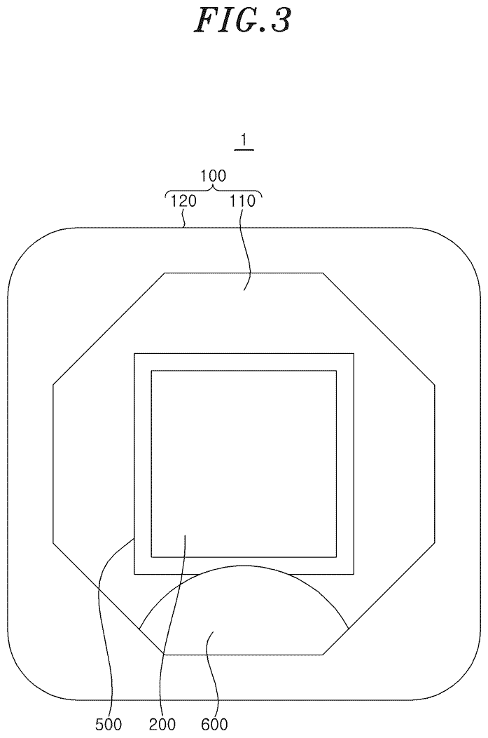

With further reference to FIGS. 3 to 5, the second reflective layer 600 may be positioned between the light emitting device 200 and the sidewall 120 to cover the protective device 400.

With reference to FIG. 3, as a first example, the second reflective layer 600 may be disposed to cover at least one region of the protective device 400, and may reduce a loss of light absorbed by the protective device 400. In this case, a height of the second reflective layer 600 may be higher than the protective device 400 to sufficiently cover the protective device 400. The second reflective layer 600 may be disposed to be spaced apart from the light emitting device 200 in order to improve the side light extraction efficiency. Since the second reflective layer 600 may be disposed to overlap at least one region of the first reflective layer 500, the reflectance may be improved more than when only a single first reflective layer 500 is disposed, and thus light extraction efficiency may be improved.

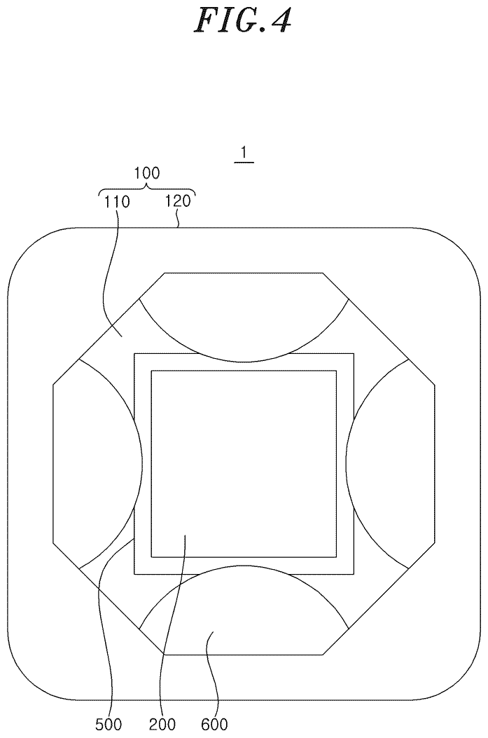

With reference to FIG. 4, as a second example, the second reflective layer 600 may be formed in plural and may be disposed to be spaced apart from each other along an inner peripheral surface of the sidewall 120. When the second reflective layer 600 is disposed in a region with a relatively wide area of the base 110, light absorption of the base 110 may be reduced, the light extraction efficiency may be increased, and the amount of light may be increased. An exposed area of the base 110 may be equal to or less than 50% of a coverage area of the second reflective layer 600. In addition, the second reflective layer 600 may be disposed to overlap at least one region of the first reflective layer 500, thereby reducing discoloration and the improving reliability. The second reflective layer 600 may be disposed in at least one region of the sidewall 120. The coverage area of the second reflective layer 600 may correspond to the area of the base 110 covered by the second reflective layer 600, but is not limited thereto.

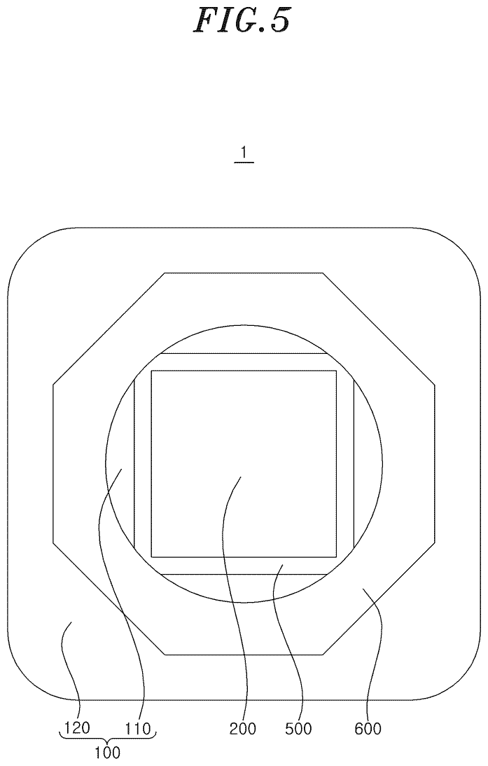

With reference to FIG. 5, as a third example, the second reflective layer 600 may be disposed in at least one region of the sidewall 120. The second reflective layer 600 may reflect light that is absorbed by the sidewall 120, thereby reducing light loss and reflecting the light to an upper surface to improve light extraction efficiency. In addition, the second reflective layer 600 may be disposed to overlap at least one region of the first reflective layer 500, thereby protecting the first reflective layer 500, reducing discoloration, and improving the reliability. An exposed area of the base 110 may be equal to or less than 50% of a coverage area of the second reflective layer 600, which can help increase the amount of light absorbed at the surface of the base 110. When viewed from above, the distance between the side surface of the light emitting device 200 and the edge of the first reflective layer 500 may be shorter than the length of the cross-section of the light emitting device 200. Likewise, when viewed from above, the distance between the edge of the first reflective layer 500 and the second reflective layer 600 may also be shorter than the length of the cross-section of the light emitting device 200. For example, when viewed from above, the distance between the side surface of the light emitting device 200 and the edge of the first reflective layer 500 may be 20% or more and less than 80% of the cross-sectional length of the light emitting device 200. Further, the distance between the edge of the first reflective layer 500 and the second reflective layer 600 may be 10% or more and less than 50% of the length of the light emitting device 200. This configuration helps secure reflectivity, thereby improving the light extraction efficiency and reducing production costs. Furthermore, the second reflective layer 600 may be arranged continuously, which can lower the design complexity. Further, the second reflective layer 600 may also leave a portion of the base 110 exposed, thereby reducing processing costs.

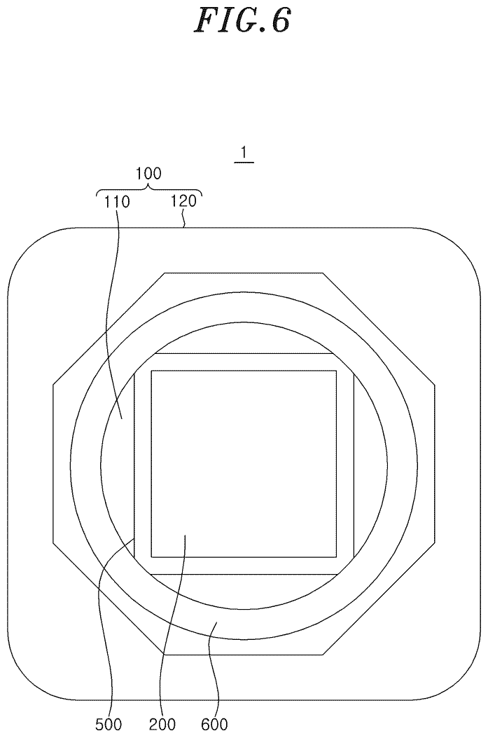

With reference to FIG. 6, as a fourth example, the second reflective layer 600 may be extended along the inner peripheral surface of the sidewall 120, and surround the light emitting device 200. The second reflective layer 600 may be spaced apart from the light emitting device 200 and the sidewall 120 and be disposed therebetween, and may be disposed such that at least one region faces the light emitting device 200, and another region opposite the one region faces the sidewall. In other words, one region of the second reflective layer 600 may face a side surface of the light emitting device 200, and another region of the second reflective layer 600 may face the inner peripheral surface of the sidewall 120. In addition, the second reflective layer 600 may not cover the sidewall 120. By such a second reflective layer 600, the side surface and upper surface of the sidewall 120 may not be contaminated by fumes coming from the second reflective layer 600 during a process, and interference with a lens adhesion portion adhered to the sidewall 120 in a post-process may be reduced, thereby increasing structural stability and reducing the lens separation. At least one region of the second reflective layer 600 may be spaced apart from the light emitting device 200. In other words, at least one region of the second reflective layer 600 may be spaced apart without covering a side surface of the light emitting device 200, thereby preventing the second reflective layer 600 from touching the light emitting device 200, absorbing light, or being broken by heat of the light emitting device 200, thus improving the amount of light and the reliability.

A thickness of the second reflective layer 600 may increase toward the sidewall 120. In other words, a thickness of at least one region of the second reflective layer 600 may be smaller than a thickness of another region of the second reflective layer 600. The second reflective layer 600 may be connected to the first reflective layer 500. In other words, a portion of a lower surface of the second reflective layer 600 may be connected to the first reflective layer 500, and another portion thereof may be connected to the base 110. In addition, a surface of the second reflective layer 600 may be formed as a curved surface by being concavely formed downward due to the surface tension of a mold portion.

Since light may be efficiently reflected at the second reflective layer 600, there is an effect that a surface light emission effect of the light emitting module 1 may be improved.

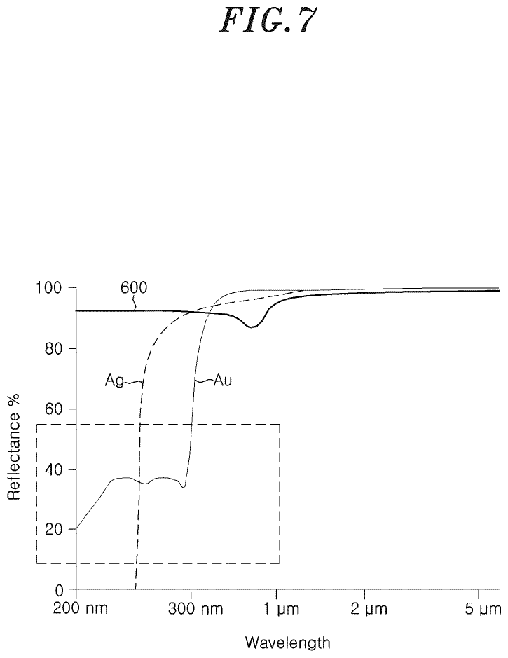

With further reference to FIG. 7, in reflectance of a material according to a wavelength, the second reflective layer 600 may efficiently reflect short-wavelength light, so that the light emitting module 1 may efficiently generate UV light. For example, when Au or Ag is plated in at least one region of the substrate 100 or the first reflective layer 500, reflectance of the substrate 100 for light in a wavelength band of 350 nm or less may be formed to be 40% or less, whereas reflectance of the second reflective layer 600 for light in a wavelength band of 350 nm or less may be formed to be 90% or more. In addition, in case of Ag, reflectance decreases at the 300 nm wavelength band, which may degrade light uniformity of a product in the UVB region. In general, even a light emitting device may have a light deviation of about 7 nm even in a product at the same wavelength band. For example, when the light emitting device is a light emitting device that emits light in the 300 nm region, there may be a problem in which the light yield decreases due to differences in the reflectance even among products of the same production lot. However, when the second reflective layer 600 is applied, the reflectance in the 300 nm wavelength range can be made more gradual or consistent. In this case, the difference in the reflectance between wavelengths equal to or below 300 nm and visible light wavelengths (e.g., 500 nm) in the second reflective layer 600 may be less than 10%. In addition, the second reflective layer 600 may exhibit higher reflectance than the first reflective layer 500 at wavelengths equal to or below 300 nm. The reflectance of the second reflective layer 600 at 300 nm may be 1.5 to 2.5 times that of the first reflective layer 500. As the reflectance increases gradually due to the second reflective layer 600, the light extraction efficiency can be improved. Moreover, the second reflective layer 600 may include aluminum. The atomic content of aluminum in the second reflective layer 600 may range from 15% to less than 40%, which can contribute to reducing production costs.

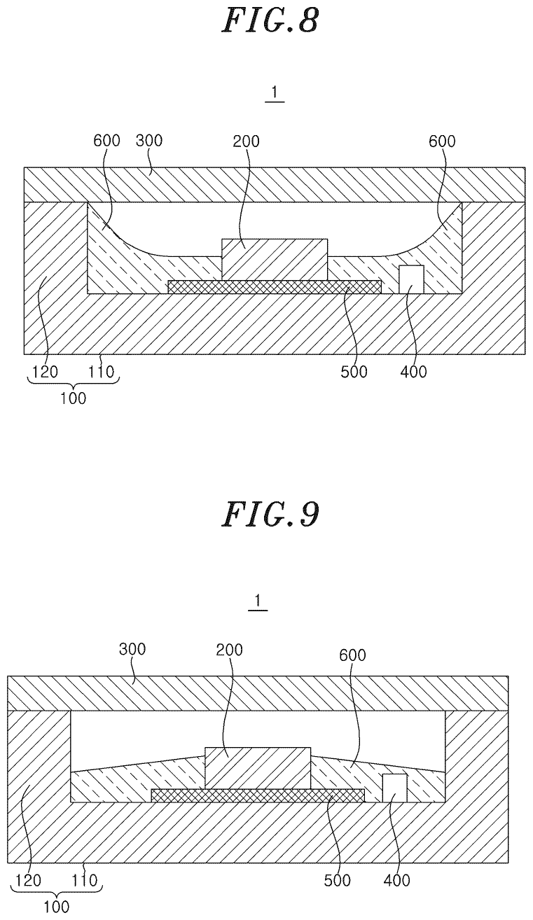

Hereinafter, with reference to FIG. 8, a light emitting module 1 according to a second embodiment of the disclosed technology will be described. In describing the second embodiment, when compared with the first embodiment, there is a difference in that the second reflective layer 600 is connected to the light emitting device 200, and thus the difference will be mainly described.

The second reflective layer 600 may be connected to the light emitting device 200. In other words, one region of the second reflective layer 600 may be disposed on one side surface of the light emitting device 200, and may reduce light emitted to the side surface of the light emitting device 200 and increase light emitted to the upper surface, thereby narrowing an emission angle. In addition, a thickness of one region of the second reflective layer 600 may be smaller than a thickness of another region. A thickness of a region (one region) of the second reflective layer 600 adjacent to the light emitting device 200 and a thickness of a region (another region) of the second reflective layer 600 adjacent to the sidewall 120 may be different from each other. For example, a thickness of the second reflective layer 600 disposed on one side surface of the light emitting device 200 may be thinner than a thickness of the second reflective layer 600 disposed on one side surface of the sidewall 120. The thickness of the second reflective layer 600 may become thicker as it becomes farther from the light emitting device 200, and may gradually reduce a reflection angle as it goes outward, thereby narrowing an emission angle and increasing the luminance of the light emitting module 1 in one region. The second reflective layer 600 may be formed such that its inclination with respect to the base 110 varies by region. For example, the region of the second reflective layer 600 adjacent to the light emitting device 200 may have the lowest inclination, while the region near the sidewall 120 may have the highest inclination. As the distance from the light emitting device 200 increases, the second reflective layer 600 may reflect light toward the central region of the light emitting module 1, thereby narrowing the emission angle and increasing the luminance. Additionally, the second reflective layer 600 may be formed with a curved surface, where the curvature varies by region. In a first example, the curvature of a region of the second reflective layer 600 may increase toward the outer edge.

In a second example, the curvature of a first region of the second reflective layer 600, which is adjacent to the light emitting device 200, may be smaller than the curvature of a second region located between the first region and the sidewall 120.

In a third example, the radius of curvature of the second region may be smaller than that of a third region of the second reflective layer 600, which is adjacent to the sidewall 120. The second region may be positioned between the first region and the third region. This may allow the reflection angle to gradually decrease, thereby narrowing the emission angle and increasing the luminance of the light emitting module 1 in one region.

In addition, a thickness of one region of the second reflective layer 600 may be formed to be greater than a thickness of the first reflective layer 500. In addition, since the second reflective layer 600 is in contact with the light emitting device 200, an outer surface of the first reflective layer 500 may be entirely covered, so that not only sufficient reflectance is secured, but also the first reflective layer 500 is protected from moisture penetration to prevent oxidation and improve reliability. The maximum thickness of the first reflective layer 500 may be 2% to 20% of the maximum thickness of the second reflective layer 600 in a vertical direction. This can reduce design complexity.

Hereinafter, with reference to FIG. 9, a light emitting module 1 according to a third embodiment of the disclosed technology will be described. In describing the third embodiment, when compared with the above-described embodiments, there is a difference in that a thickness of the second reflective layer 600 decreases toward the sidewall 120 from the light emitting device 200, and thus the difference will be mainly described.

The thickness of the second reflective layer 600 may decrease toward the sidewall 120. In other words, a thickness of at least one region of the second reflective layer 600 may be formed to be greater than a thickness of another region of the second reflective layer 600. The thickness of the second reflective layer 600 may have a higher thickness in a region adjacent to the light emitting device 200, and may have a lower thickness in a region adjacent to the sidewall 120. In addition, the thickness of the second reflective layer 600 may be lower than a height of the sidewall 120, and may have a region where the second reflective layer 600 is not disposed, which may minimize the interference with the reflection path of light traveling from the light emitting device 200 to the sidewall, thereby improving the amount of light by reflecting light directed to the bottom without changing the emission angle. A thickness of at least one region of the second reflective layer 600 may be formed to be greater than a thickness of the protective device 400, so that light absorbed by the protective device 400 is reduced to increase the light extraction efficiency, and the protective device 400 is protected from external moisture penetration to improve reliability. In addition, at least one region of the second reflective layer 600 may be connected to a side surface of the light emitting device 200, or may be spaced apart from the light emitting device 200. The thickness of the second reflective layer 600 may be equal to or smaller than a thickness of the light emitting device 200, and may cover one region of the light emitting device 200. The second reflective layer 600 may cover one region of the light emitting device to lengthen a moisture penetration path, thereby delaying damage to a semiconductor layer due to moisture or external gas, and improving reliability.

In addition, a thickness of one region of the second reflective layer 600 may be formed to be greater than a thickness of the first reflective layer 500. In addition, since the second reflective layer 600 is in contact with the light emitting device 200, an outer surface of the first reflective layer 500 may be entirely covered, so that not only sufficient reflectance is secured, but also the first reflective layer 500 is protected from moisture penetration to prevent oxidation and improve reliability.

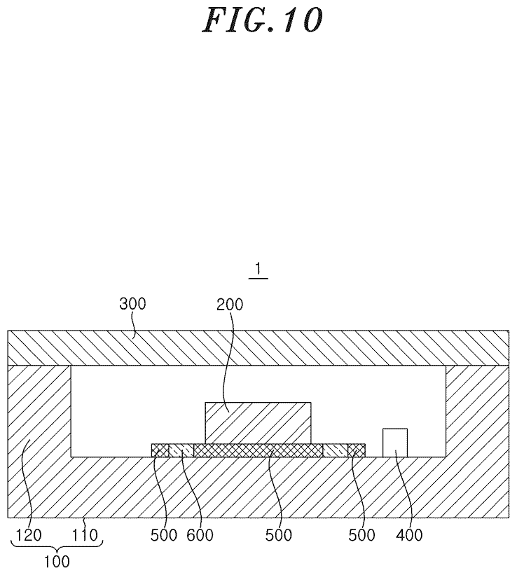

Hereinafter, with reference to FIG. 10, a light emitting module 1 according to a fourth embodiment of the disclosed technology will be described. In describing the fourth embodiment, when compared with the above-described embodiments, there is a difference in that the first reflective layer 500 may be formed in plural, and thus the difference will be mainly described.

A plurality of first reflective layers 500 may be disposed to be spaced apart from each other in a horizontal direction. In other words, one of the plurality of first reflective layers 500 may support the light emitting device 200, and another of the plurality of first reflective layers 500 may be extended along an inner peripheral surface of the sidewall 120. Another of the plurality of first reflective layers 500 may be disposed to be spaced apart from one of the plurality of first reflective layers 500. That is, one of the plurality of first reflective layers 500 may be positioned inside another of the plurality of first reflective layers 500. In this case, at least one of the plurality of first reflective layers 500 may form a peripheral surface along the inner surface.

The second reflective layer 600 may be disposed between the plurality of first reflective layers 500. In addition, the second reflective layer 600 may be extended along a peripheral surface of one of the plurality of first reflective layers 500. An inner side of such a second reflective layer 600 may be connected to one of the plurality of first reflective layers 500. In addition, an outer side of the second reflective layer 600 may be connected to another of the plurality of first reflective layers 500. In addition, the second reflective layer 600 may be disposed in one region of the base 110 in a region where the first reflective layer 500 is not disposed, so that light absorption in the base 110 may be reduced, thereby increasing an amount of light. In addition, a height of the second reflective layer 600 may be substantially similar to a height of the first reflective layer 500, and a difference therebetween may be less than 10%. Even if a height of the second reflective layer 600 is similar to a height of the first reflective layer 500, light absorption in the base 110 may be reduced without affecting an emission angle, thereby increasing an amount of light. The second reflective layer 600 may not cover one region of the base 110, and one region of the base 110 may not overlap with the second reflective layer 600. This can reduce interference between reflected light to reduce a mura phenomenon, and reduce a usage amount of a material for forming the second reflective layer 600, thereby reducing production cost. In addition, the second reflective layer 600 may not cover the protective device 400, simplify a process, and reduce a usage amount of a material for forming the second reflective layer 600, thereby reducing production cost.

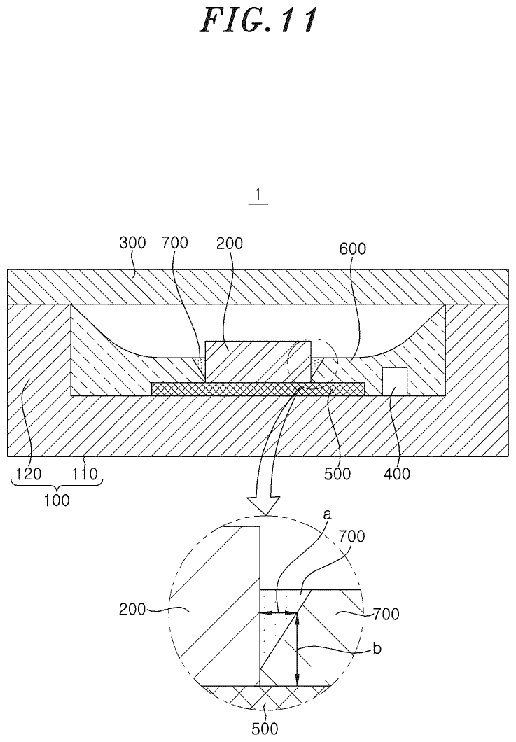

Hereinafter, with reference to FIG. 11, a light emitting module 1 according to a fifth embodiment of the disclosed technology will be described. In describing the fifth embodiment, when compared with the above-described embodiments, there is a difference in that a third light-transmitting layer 700 may be further included, and thus the difference will be mainly described.

The third light-transmitting layer 700 may be disposed between the second reflective layer 600 and the light emitting device 200 so that side light among the light generated from the light emitting device 200 is transmitted. The third light-transmitting layer 700 may have a higher light transmittance than the second reflective layer 600. Light transmitted through the third light-transmitting layer 700 may be reflected by the second reflective layer 600. By such a third light-transmitting layer 700, at least one region of the second reflective layer 600 may be spaced apart from the light emitting device 200. Since the second reflective layer 600 may have a higher reflectance than the third light-transmitting layer 700, light may be reflected by the interface of the third light-transmitting layer 700 and the second reflective layer 600, thereby increasing the light extraction efficiency. In this case, an amount of light of the light emitting module 1 when the second reflective layer 600 and the third light-transmitting layer 700 are present may be higher than an amount of light of the light emitting module 1 after the second reflective layer 600 is removed. The difference in the amount of light of the light emitting module 1 according to the presence or absence of the second reflective layer 600 may be 5% or more and less than 30%.

As a vertical distance from the base 110 increases, a width in the horizontal direction (a) from the light emitting device 200 may increase in the third light-transmitting layer 700, and by increasing the refraction distance of light and widening the light emission area in the horizontal direction, the light extraction efficiency may be improved. The third light-transmitting layer 700 may have an inclined surface in which the vertical distance (b) from the base 110 increases as the distance from the light emitting device 200 increases, and a thickness in a height direction of the third light-transmitting layer 700 decreases, may increase light uniformity by reducing a vertical movement path of a relatively long horizontal movement path of light and increasing a vertical movement path of a relatively short horizontal movement path, to make a movement distance of light uniform. By such a third light-transmitting layer 700, an inclined surface in which the height decreases toward the light emitting device 200 may be formed in one region of the second reflective layer 600. In other words, an inclined surface in which the vertical height (b) increases as the distance from the light emitting device 200 increases may be formed in one region of the second reflective layer 600. By such an inclined surface, light may be reflected toward an upper surface of the light emitting module 1, thereby increasing the light extraction efficiency.

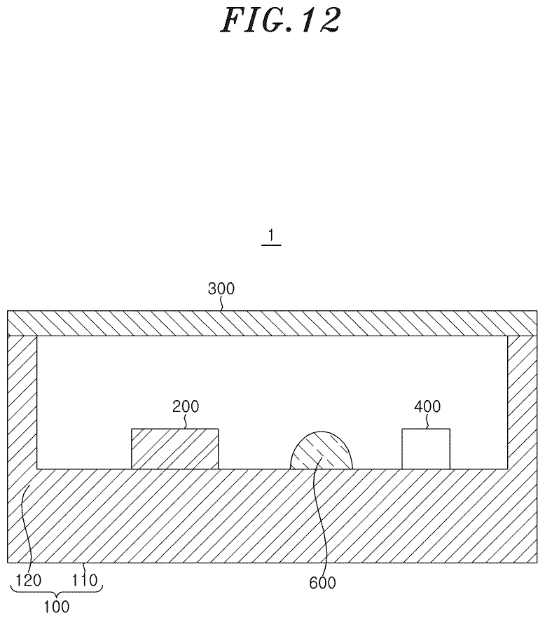

Hereinafter, with reference to FIG. 12, a light emitting module 1 according to a sixth embodiment of the disclosed technology will be described. In describing the sixth embodiment, when compared with the above-described embodiments, there is a difference in that the second reflective layer 600 may be positioned between the protective device 400 and the light emitting device 200, and thus the difference will be mainly described.

The second reflective layer 600 may be disposed between the light emitting device 200 and the protective device 400. In addition, the second reflective layer 600 may be spaced apart from the light emitting device 200 and the protective device 400. The spaced distance may be greater than a height of the light emitting device 200, and tan 0 of an angle (0) formed by one region or a vertex of a corner of the light emitting device 200 and a contact point between the second reflective layer 600 and the base 110 may be smaller than 1. This may minimize light interference and reduce light loss. A maximum height of the second reflective layer 600 may be higher than a height of the light emitting device 200 and that of the protective device 400, but is not limited thereto. The second reflective layer 600 may be spaced apart from the light emitting device 200 and the protective device 400. Such a second reflective layer 600 may reflect light that is generated from the light emitting device 200 and directed toward the protective device 400, upward. In other words, the second reflective layer 600 may block the light generated from the light emitting device 200 from directly entering the protective device 400.

In addition, an upper end of the second reflective layer 600 may have a reduced length in a horizontal direction as it goes upward, and may improve light extraction efficiency by adjusting a light path to be directed toward an upper surface of the light emitting module 1. For example, the upper end of the second reflective layer 600 may be convexly formed upward. The second reflective layer 600 may have a curved surface.

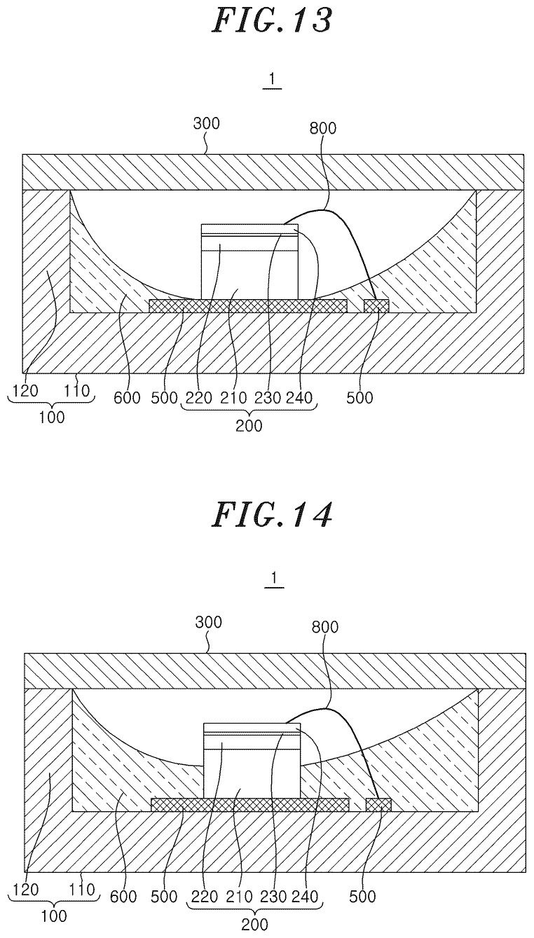

Hereinafter, with reference to FIG. 13, a light emitting module 1 according to a seventh embodiment of the disclosed technology will be described. In describing the seventh embodiment, when compared with the above-described embodiments, there is a difference in that the light emitting device 200 may be configured in a vertical chip structure, and thus the difference will be mainly described.

The light emitting device 200 may include a device substrate 210, a first conductive semiconductor layer 220, an active layer 230, and a second conductive semiconductor layer 240 in a vertical chip structure. The semiconductor layers of such a structure of the light emitting device 200 may be disposed on an upper surface of the device substrate 210. Such a light emitting device 200 may efficiently generate long-wavelength light of the UVA region in the UV light, or UVB, or long-wavelength light longer than or equal to blue light.

The device substrate 210 may be a conductive substrate. The device substrate 210 may be stacked on the first reflective layer 500 and may be electrically connected to the substrate 100. Such a device substrate 210 may reflect light and serve as a conductor. A thickness of the device substrate 210 may be formed to be greater than a length from a lower surface of the first conductive semiconductor layer 220 to an upper surface of the second conductive semiconductor layer 240.

The first conductive semiconductor layer 220 may be stacked on the device substrate 210. The first conductive semiconductor layer 220 may include p-type impurities (e.g., Mg, Sr, Ba). In this case, in the seventh embodiment, the first conductive semiconductor layer 220 may be a p-type semiconductor layer. However, this is merely an example, and the first conductive semiconductor layer 220 may include n-type impurities.

The active layer 230 may include a multiple quantum well (MQW) structure, and a composition ratio of a nitride-based semiconductor may be adjusted so as to emit a desired wavelength. Such an active layer 230 may be stacked on the first conductive semiconductor layer 220. In other words, the active layer 230 may be positioned between the first conductive semiconductor layer 220 and the second conductive semiconductor layer 240.

The second conductive semiconductor layer 240 may be stacked on the active layer 230. The second conductive semiconductor layer 240 may include n-type impurities (e.g., Si, Ge, Sn), and in this case, in the seventh embodiment, the second conductive semiconductor layer 240 may be an n-type semiconductor layer. However, this is merely an example, and the second conductive semiconductor layer 240 may also include p-type impurities.

In addition, the second conductive semiconductor layer 240 may be electrically connected to the base 110 through a conductor 800. One region of the conductor 800 may be connected to the second conductive semiconductor layer 240, and another region opposite the one region may be disposed on the base 110. The conductor 800 may be a metal wire. In this case, the conductor 800 may be disposed on one surface of the first reflective layer 500. The conductor 800 may include the same material as the first reflective layer 500, and by enhancing adhesive force between the conductor 800 and the first reflective layer 500, the thermal shock reliability may be improved. As an example, the first reflective layer 500 and the conductor 800 may include gold, silver, copper, nickel, palladium, aluminum, tin, or the like, or may include alloys of these metals.

At least one of the device substrate 210, the first conductive semiconductor layer 220, the active layer 230, or the second conductive semiconductor layer 240 may include the same material as the second reflective layer 600. For example, at least one of the device substrate 210, the first conductive semiconductor layer 220, the active layer 230, or the second conductive semiconductor layer 240 may include aluminum. Since at least one of the device substrate 210, the first conductive semiconductor layer 220, the active layer 230, or the second conductive semiconductor layer 240 may include the same material as the second reflective layer 600, light emission efficiency and reflection efficiency at the emission wavelength of the light emitting module 1 may be improved, and in this case, the emission wavelength band may be in the UV region.

Meanwhile, in the seventh embodiment, the second reflective layer 600 may be formed as described in the first to fifth embodiments above, and will be described accordingly.

With further reference to FIGS. 13 to 15, one region of the second reflective layer 600 may be spaced apart from or be in contact with the device substrate 210. In addition, the thickness of the second reflective layer 600 may increase or decrease toward the sidewall 120. By such a second reflective layer 600, one region of the conductor 800 may be embedded in and fixed to the second reflective layer 600. Another region of the conductor 800 may not be embedded in the second reflective layer 600, and may be exposed to the outside. In addition, one region of the first reflective layer 500 may be disposed in a region below a boundary between the device substrate 210 and the first conductive semiconductor layer 220. In other words, at least one region of the boundary between the first conductive semiconductor layer 220 and the device substrate 210 may not be covered by the second reflective layer 600, and may be exposed to the outside. As a result, light emitted from the semiconductor layer may not be covered by the second reflective layer 600, and may be emitted to a side region, thereby increasing the light extraction efficiency. The thickness of one region of the second reflective layer 600 may be smaller than the thickness of the device substrate 210. The minimum thickness of the second reflective layer 600 in the vertical direction may be less than the minimum thickness of the device substrate 210 in the vertical direction.

With reference to FIG. 13, one region of the second reflective layer 600 may be spaced apart from the device substrate 210. The second reflective layer 600 may be disposed on at least one region of the first reflective layer 500. The second reflective layer 600 may expose one region of the first reflective layer 500. The first reflective layer 500 may be exposed in an adjacent region of the light emitting device 200. The first reflective layer 500 and the second reflective layer 600 may have a different reflectance, and the exposed first reflective layer 500 may reduce an interference phenomenon of the light emitting module 1, thereby reducing mura phenomenon and increasing the light uniformity.

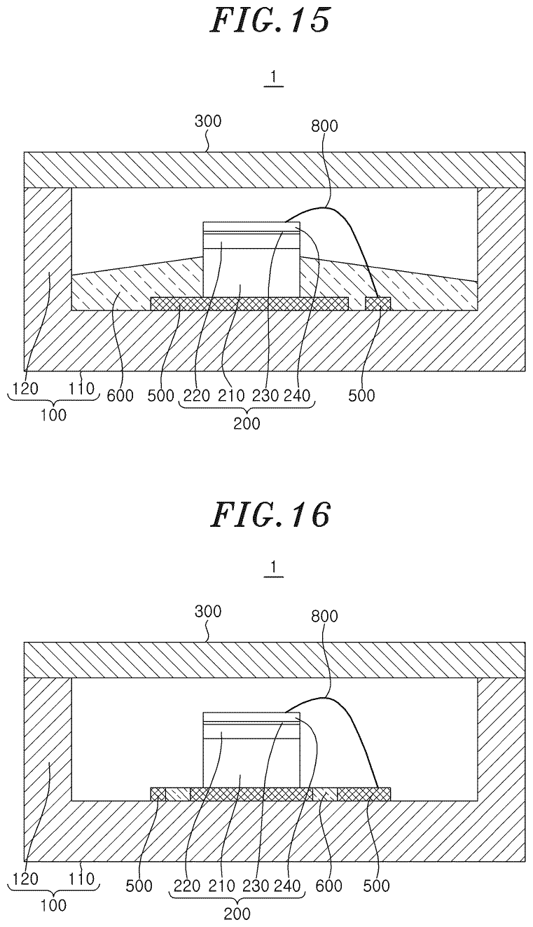

With reference to FIGS. 14 to 15, one region of the second reflective layer 600 may be disposed on one region of the light emitting device 200. In addition, the second reflective layer 600 may be disposed on at least one region of the device substrate 210, and the device substrate 210 of the light emitting device 200 may have a reflectance lower than that of the second reflective layer 600. Therefore, when the second reflective layer 600 is disposed on one region of the device substrate 210, the light absorption at the device substrate 210 may be reduced, thereby increasing the amount of light.

With reference to FIG. 14, a curvature may be formed on at least one region of the second reflective layer 600. The second reflective layer 600 may have a concave shape downward. Through the curved region, light may be concentrated in one region, thereby narrowing the emission angle and increasing the luminance in the one region. In this case, the curvatures of one region and another region centered on the light emitting device 200 may be different from each other, and the second reflective layer 600 may compensate for the non-uniformity of the light emission pattern of the light emitting device 200, thereby increasing the light uniformity.

With reference to FIG. 15, the second reflective layer 600 may have a linear region in at least one region. The second reflective layer 600 may have a shape in which a height decreases toward the sidewall 120. The second reflective layer 600 may expose the sidewall 120, and may absorb a portion of the light emitted to the side, thereby reducing the chromatic aberration according to the emission angle. In this case, lengths of linear regions of one region and another region centered on the light emitting device 200 may be different from each other, and the second reflective layer 600 may compensate for the non-uniformity of the light emission pattern of the light emitting device 200, thereby increasing the light uniformity.

With reference to FIG. 16, the second reflective layer 600 may be disposed between the plurality of first reflective layers 500 and may increase an amount of light while reducing the interference in the light path and reducing a variation in an emission angle. The device substrate 210 may be disposed on an upper side of one of the plurality of first reflective layers 500. The conductor 800 may not be embedded in the second reflective layer 600, may be exposed to the outside, and may be electrically connected to at least one of the first reflective layers 500.

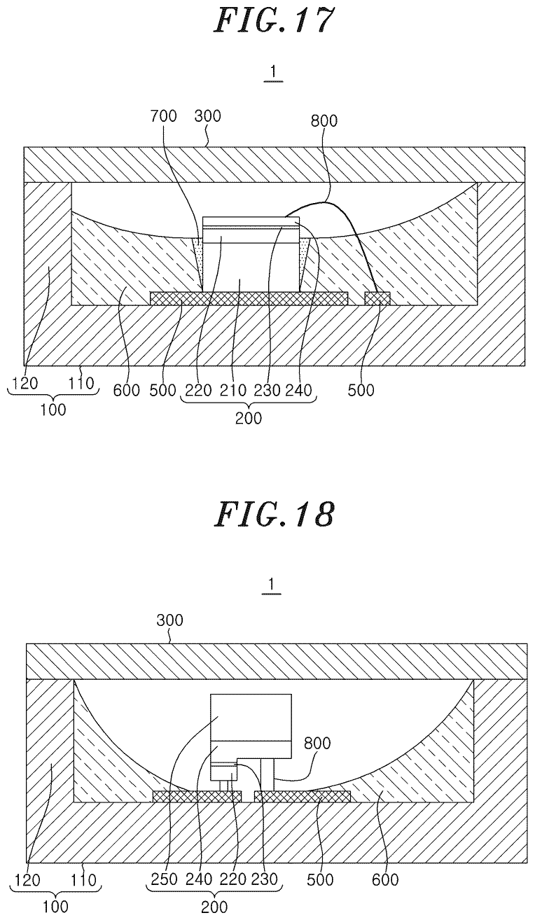

With reference to FIG. 17, a third light-transmitting layer 700 may be disposed between the second reflective layer 600 and the device substrate 210. The third light-transmitting layer 700 may be disposed on at least one side region of the light emitting device 200. In other words, the third light-transmitting layer 700 may be disposed on at least one side region of the device substrate 210, such that the second reflective layer 600 and the device substrate 210 may be spaced apart from each other, and damage to the second reflective layer 600 caused by heat from the light emitting device 200 may be reduced, thereby improving the reliability. In addition, a thickness of the third light-transmitting layer 700 may be equal to or higher than a thickness of the device substrate 210. The third light-transmitting layer 700 may cover at least one region of a semiconductor layer of the light emitting device 200, and may be disposed on one region of at least one of the first conductive semiconductor layer 220, the active layer 230, or the second conductive semiconductor layer 240. The third light-transmitting layer 700 may refract a portion of light emitted from a side surface of the semiconductor layer. The third light-transmitting layer 700 may be disposed between the second reflective layer 600 and the light emitting device 200 so that side light among the light generated from the light emitting device 200 is transmitted.

The third light-transmitting layer 700 may have a higher light transmittance than the second reflective layer 600. Light transmitted through the third light-transmitting layer 700 may be reflected by the second reflective layer 600. The second reflective layer 600 may have a higher reflectance than the third light-transmitting layer 700, and light may be reflected at the interface between the third light-transmitting layer 700 and the second reflective layer 600, thereby increasing the light extraction efficiency. In this case, an amount of light of the light emitting module 1 when the second reflective layer 600 and the third light-transmitting layer 700 are present may be higher than an amount of light of the light emitting module 1 after the second reflective layer 600 and the third light-transmitting layer 700 are removed. The difference in the amount of light of the light emitting module 1 according to the presence or absence of the third light-transmitting layer 700 may be 5% or more and less than 30%.

As a vertical distance from the base 110 increases, a width in the horizontal direction from the light emitting device 200 may increase in the third light-transmitting layer 700, and by increasing the refraction distance of light and widening the light emission area in the horizontal direction, the light extraction efficiency may be improved. The third light-transmitting layer 700 may have an inclined surface such that, as the distance from the light emitting device 200 increases, the vertical distance from the base 110 increases, while the thickness of the third light-transmitting layer 700 in the vertical direction decreases. The inclined surface may reduce a vertical movement path of a relatively long horizontal movement path of light and increase a vertical movement path of a relatively short horizontal movement path, thereby making a movement distance of light uniform and increasing the light uniformity.

Hereinafter, with reference to FIG. 18, a light emitting module 1 according to an eighth embodiment of the disclosed technology will be described. In describing the eighth embodiment, when compared to the above-described embodiments, there is a difference in that electrodes of the light emitting device 200 may be configured to be on the same surface, and thus the difference will be mainly described.

The light emitting device 200 may be formed in a structure in which electrodes are on the same surface, and may include the first conductive semiconductor layer 220, the active layer 230, the second conductive semiconductor layer 240, and the first light-transmitting layer 250. The light emitting device 200 may be in a form in which the first light-transmitting layer 250 is positioned on an upper surface of the light emitting device 200, and may emit light efficiently through the first light-transmitting layer 250. In addition, the first light-transmitting layer 250 may be positioned on a lower surface of the light emitting device 200, and light may be extracted also to a side surface through the first light-transmitting layer 250.

The first conductive semiconductor layer 220 may be electrically connected to the base 110. The first conductive semiconductor layer 220 may include n-type impurities (e.g., Si, Ge, Sn), and in this case, in the eighth embodiment, the first conductive semiconductor layer 220 may be an n-type semiconductor layer. However, this is merely an example, and the first conductive semiconductor layer 220 may also include p-type impurities.

The active layer 230 may be stacked on the first conductive semiconductor layer 220. In other words, the active layer 230 may be positioned between the first conductive semiconductor layer 220 and the second conductive semiconductor layer 240.

The second conductive semiconductor layer 240 may be stacked on the active layer 230 and may be electrically connected to the base 110. The second conductive semiconductor layer 240 may include p-type impurities (e.g., Mg, Sr, Ba). In this case, in the eighth embodiment, the second conductive semiconductor layer 240 may be a p-type semiconductor layer. However, this is merely an example, and the second conductive semiconductor layer 240 may also include p-type impurities.

The first light-transmitting layer 250 may be stacked on the second conductive semiconductor layer 240. The first light-transmitting layer 250 may be an insulating or conductive substrate for growing the first conductive semiconductor layer 220, the active layer 230, and the second conductive semiconductor layer 240. For example, the first light-transmitting layer 250 may include at least one of a sapphire substrate, a silicon carbide substrate, a silicon substrate, a gallium nitride substrate, or an aluminum nitride substrate.

Meanwhile, in the eighth embodiment, the second reflective layer 600 may be formed as described in the above-mentioned first to fifth embodiments, and will be described accordingly.

With further reference to FIGS. 18 and 20, at least one region of the second reflective layer 600 may be spaced apart from or connected to the first light-transmitting layer 250. A thickness of the second reflective layer 600 from the base 110 may increase or decrease toward the sidewall 120. In addition, when one region of the second reflective layer 600 is connected to the first light-transmitting layer 250, a region between the second conductive semiconductor layer 240 and the first light-transmitting layer 250 may be disposed lower in the vertical direction than a side surface of the second reflective layer 600. In other words, the region between the second conductive semiconductor layer 240 and the first light-transmitting layer 250 may be covered by the second reflective layer 600 and may not be exposed to the outside.

With reference to FIG. 18, one region of the second reflective layer 600 may be spaced apart from the first light-transmitting layer 250. The second reflective layer 600 may be disposed on at least one region of the first reflective layer 500. The second reflective layer 600 may expose at least one region of the first reflective layer 500. The first reflective layer 500 may be exposed in an adjacent region of the light emitting device 200. The first reflective layer 500 and the second reflective layer 600 may have different reflectance, and the exposed first reflective layer 500 may reduce an interference phenomenon of the light emitting module 1, thereby reducing a mura phenomenon and increasing the light uniformity.

The second reflective layer 600 may be disposed to be spaced apart from the first light-transmitting layer 250, and may reduce the interference with light emitted toward a side surface of the first light-transmitting layer 250, thereby widening an emission angle and increasing the amount of light. In addition, the second reflective layer 600 may have a shape increasing toward the sidewall 120. A region of the second reflective layer 600 disposed in one region of the sidewall 120 may have a maximum height. In this case, a maximum height of the second reflective layer 600 may be higher than a height of the first light-transmitting layer 250, and may be higher than the light emitting device 200. The second reflective layer 600 may reflect light emitted toward the side surface of the first light-transmitting layer 250 upward, thereby improving the light extraction efficiency.

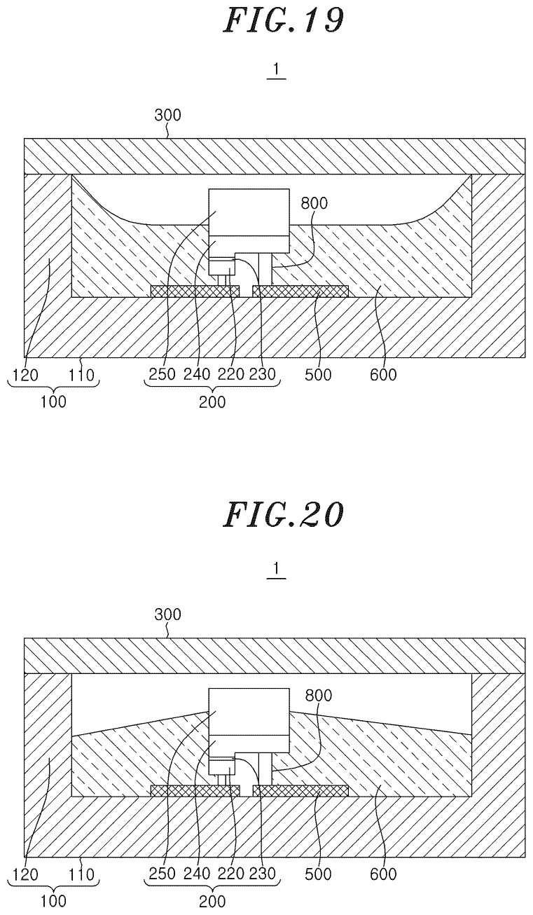

With reference to FIGS. 19 and 20, at least one region of the second reflective layer 600 may be disposed in one region of the light emitting device 200. In addition, the second reflective layer 600 may expose at least one region of the first light-transmitting layer 250. The first light-transmitting layer 250 may have a higher transmittance than the second reflective layer 600. Accordingly, when the second reflective layer 600 is disposed in one region of the first light-transmitting layer 250, the light emitted from one region of the first light-transmitting layer 250 may be reflected upward, thereby narrowing the emission angle and increasing the luminance. The second reflective layer 600 may cover at least one region of one of the first conductive semiconductor layer 220, the active layer 230, or the second conductive semiconductor layer 240 of the light emitting device 200, and may reflect a portion of the light generated in the semiconductor layer upward to increase the luminance, and may protect the semiconductor layer from moisture or contaminant gas, thereby improving the reliability.

In addition, the second reflective layer 600 may be disposed in one region of a mesa region between the first conductive semiconductor layer 220, the active layer 230, or the second conductive semiconductor layer 240, and may improve the reliability by providing protection from contaminant gas. In addition, the second reflective layer 600 may be disposed on one region of the conductor 800 and the first reflective layer 500 to enhance the physical adhesive force, thereby reducing a separation of an adhesive surface of the conductor 800 caused by thermal shock, and improving the reliability. In addition, the second reflective layer 600 may be disposed in a region between the conductor 800 electrically connected to the first conductive semiconductor layer 220 and the conductor 800 electrically connected to the second conductive semiconductor layer 240, and may serve as an underfill for transferring heat to dissipate the heat generated from the light emitting device 200, thereby improving the thermal reliability.

With reference to FIG. 19, the second reflective layer 600 may have a curvature in at least one region. The second reflective layer 600 may have a concave shape downward. By such curvature, the light may be concentrated on one region, thereby narrowing the emission angle and increasing the luminance. In this case, the curvature of one region and another region of the second reflective layer 600 centered on the light emitting device 200 may be different from each other. The second reflective layer 600 may improve the light uniformity by compensating for the non-uniformity of the light emission pattern of the light emitting device 200. Specifically, one region of the second reflective layer 600 adjacent to the second conductive semiconductor layer 240 may have a wider width than other regions, and may improve the light uniformity by compensating for the non-uniformity of the light emission pattern of the light emitting device 200.

With reference to FIG. 20, the second reflective layer 600 may have a linear region in at least one region. The second reflective layer 600 may have a shape in which a height decreases toward the sidewall 120. The second reflective layer 600 may expose the sidewall 120, and may absorb a portion of light emitted to the side, thereby reducing a chromatic aberration according to the emission angle. In this case, lengths of linear regions of one region and another region centered on the light emitting device 200 may be different from each other, and the second reflective layer 600 may compensate for the non-uniformity of the light emission pattern of the light emitting device 200, thereby increasing the light uniformity.

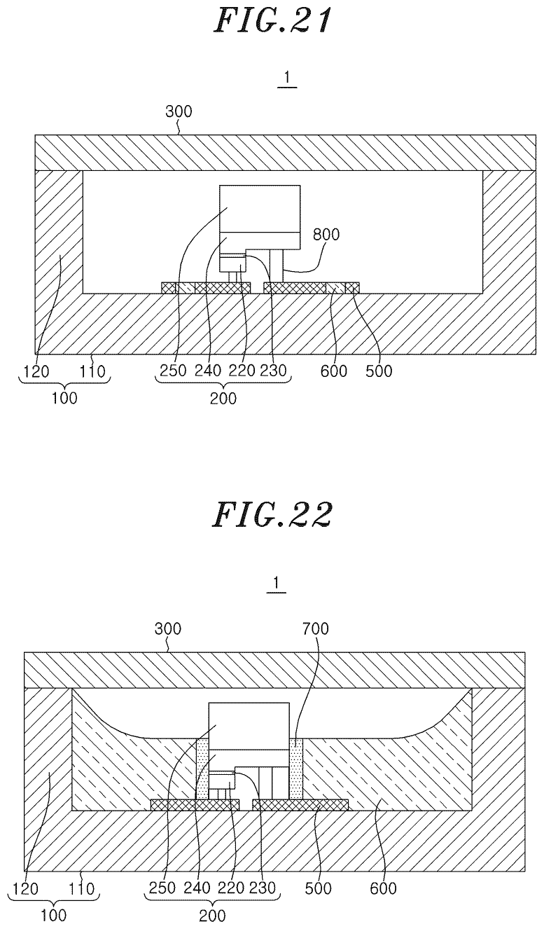

With reference to FIG. 21, the second reflective layer 600 may be disposed between the plurality of first reflective layers 500 and may increase an amount of light while reducing the interference in the light path and reducing a variation in an emission angle. The conductor 800 may not be embedded in the second reflective layer 600, may be exposed to the outside, and may be electrically connected to at least one of the first reflective layers 500.

With reference to FIG. 22, the third light-transmitting layer 700 may be disposed between the second reflective layer 600 and the first light-transmitting layer 250. The third light-transmitting layer 700 may be disposed in one region of the light emitting device 200. In other words, the third light-transmitting layer 700 may be disposed in one side region of the first light-transmitting layer 250, so that the second reflective layer 600 and the first light-transmitting layer 250 may be spaced apart from each other, and damage to the second reflective layer 600 due to heat from the light emitting device 200 may be reduced, thereby improving the reliability. In addition, the thickness of the third light-transmitting layer 700 may be formed to be equal to or higher than the height from an upper surface of the base 110 to an upper surface of the second conductive semiconductor layer 240. The third light-transmitting layer 700 may cover one region of the light emitting device 200, and may be disposed on one region of at least one of the first conductive semiconductor layer 220, the active layer 230, or the second conductive semiconductor layer 240. The third light-transmitting layer 700 may refract a portion of the light emitted from the side surface of the semiconductor layer or the first light-transmitting layer 250.

The third light-transmitting layer 700 may have a higher light transmittance than the second reflective layer 600. Light transmitted through the third light-transmitting layer 700 may be reflected by the second reflective layer 600. The second reflective layer 600 may have a higher reflectance than the third light-transmitting layer 700, and light may be reflected at the interface between the third light-transmitting layer 700 and the second reflective layer 600, thereby increasing the light extraction efficiency.

The refractive index of the third light-transmitting layer 700 may be lower than the refractive index of the first light-transmitting layer 250. When the light that has passed through the first light-transmitting layer 250 passes through the third light-transmitting layer 700 having a lower refractive index than the first light-transmitting layer 250, the third light-transmitting layer 700 may cause the refractive index change of the light to change stepwise, thereby reducing the total reflection and increasing the light extraction efficiency.

As a vertical distance from the base 110 increases, a width in the horizontal direction from the light emitting device 200 may increase in the third light-transmitting layer 700, and by increasing the refraction distance of light and widening the light emission area in the horizontal direction, the light extraction efficiency may be improved. The third light-transmitting layer 700 may have an inclined surface in which a vertical distance from the base 110 increases as a distance from the light emitting device 200 increases, and a thickness in a height direction of the third light-transmitting layer 700 decreases. The inclined surface may reduce a vertical movement path of a relatively long horizontal movement path of light and increase a vertical movement path of a relatively short horizontal movement path, thereby making a movement distance of light uniform and increasing the light uniformity.

The examples of the present disclosure have been described above as specific embodiments, but these are only examples, and the present disclosure is not limited thereto, and should be construed as having the widest scope according to the technical spirit disclosed in the present specification. A person skilled in the art may combine/substitute the disclosed embodiments to implement a pattern of a shape that is not disclosed, but it also does not depart from the scope of the present disclosure. In addition, those skilled in the art can easily change or modify the disclosed embodiments based on the present specification, and it is clear that such changes or modifications also belong to the scope of the present disclosure.

Further, exemplary embodiments are described in the following paragraphs.

In accordance with one embodiment of the present disclosure, there may be provided a light emitting apparatus including: a substrate; a light emitting device disposed on the substrate and generating light; a second light-transmitting layer disposed on the substrate so that light generated from the light emitting device passes through; a first reflective layer disposed between the substrate and the light emitting device; and a second reflective layer disposed on the substrate and reflecting light toward the second light-transmitting layer, wherein the substrate includes a base and a sidewall extending upward from the edge region of the base, and the second reflective layer is disposed between the sidewall and the light emitting device.

Further, there may be provided the light emitting apparatus further including a protective device disposed on the base so as to be disposed between the sidewall and the light emitting device, wherein the second reflective layer covers at least a region of the protective device.

Further, the sidewall may have a protrusion on at least one region of an inner or outer peripheral surface thereof.

Further, the second reflective layer may have a thickness that decreases toward the sidewall.

Further, a surface area of the first reflective layer may be formed smaller than that of the second reflective layer.

Further, a thickness of the first reflective layer may be greater than that of the second reflective layer.

Further, at least one region of the second reflective layer may cover at least one region of the first reflective layer.

Further, the protective device may be disposed on the base, and the second reflective layer may be arranged to cover a region of the protective device.

Further, the second reflective layer may include a plurality of second reflective layers that are arranged spaced apart from each other along the inner peripheral surface of the sidewall.

Further, the second reflective layer may be arranged along the inner peripheral surface of the sidewall, and the second reflective layer may be arranged continuously.

Further, the second reflective layer may expose a portion of the base.

Further, the second reflective layer may be disposed spaced apart from the light emitting device or the sidewall.

Further, the reflectivity of the second reflective layer may be higher than that of the first reflective layer at wavelengths of 300 nm or less.

Further, the second reflective layer may include aluminum.

In accordance with one embodiment of the present disclosure, there may be provided a light emitting apparatus including: a substrate; a light emitting device disposed on the substrate; a second light-transmitting layer disposed on the substrate and configured to transmit the light emitted from the light emitting device; a first reflective layer disposed between the substrate and the light emitting device; and a second reflective layer supported on the substrate and configured to reflect light toward the second light-transmitting layer, wherein the substrate includes a base and a sidewall extending upward from an edge of the base, and the second reflective layer is disposed on a side surface of the light emitting device.

Further, there may be provided the light emitting apparatus further including a protective device disposed on the base so as to be disposed between the sidewall and the light emitting device, wherein the second reflective layer covers at least a region of the protective device.

Further, the sidewall may have a protrusion on at least one region of an inner or outer peripheral surface thereof.

Further, a thickness of a region of the second reflective layer adjacent to the light emitting device may be smaller than a thickness of a region of the second reflective layer adjacent to the sidewall.

Further, the region of the second reflective layer adjacent to the light emitting device may have the smallest inclination angle, while the region of the second reflective layer adjacent to the sidewall may have the largest inclination angle.

Further, the second reflective layer may have a curvature, with a second region located between the second reflective layer and the sidewall having a greater curvature than a first region adjacent to the light emitting device.

Further, the first region may be disposed between the second region and the light emitting device.

Further, the second reflective layer may have different radii of curvature in different regions, and the radius of curvature of a third region adjacent to the sidewall may be larger than that of the second region between the light emitting device and the sidewall.

Further, the second region may be disposed between the third region and the light emitting device.

Further, a surface area of the first reflective layer may be formed smaller than a surface area of the second reflective layer.

Further, at least one area of the first reflective layer may cover at least one area of the second reflective layer.

Further, the protective device is disposed on the base, and the second reflective layer may be arranged to cover one area of the protective device.

Further, the second reflective layer may include a plurality of second reflective layers, and at least one of the plurality of second reflective layers may be arranged spaced apart from each other along the inner peripheral surface of the sidewall.

Further, the second reflective layer may be arranged along the inner peripheral surface of the sidewall, and the second reflective layer may be arranged continuously.

Further, the second reflective layer may expose a region of the base.

Further, the second reflective layer may be disposed spaced apart from the light emitting device or the sidewall.

Further, the reflectivity of the second reflective layer may be higher than that of the first reflective layer at wavelengths of 300 nm or less.

Further, the second reflective layer may include aluminum.

In accordance with one embodiment of the present disclosure, there may be provided a light emitting apparatus including: a substrate; a light emitting device disposed on the substrate and configured to emit light; a second light-transmitting layer disposed on the substrate and configured to transmit the light emitted from the light emitting device; a first reflective layer disposed between the substrate and the light emitting device; and a second reflective layer disposed on the substrate and configured to reflect light toward the second light-transmitting layer, wherein the substrate includes a base and a sidewall extending upward from an edge of the base, and the second reflective layer is disposed on a side surface of the light emitting device.

Further, there may be provided the light emitting apparatus further including a protective device disposed on the base so as to be disposed between the sidewall and the light emitting device, wherein the second reflective layer covers at least a region of the protective device.

Further, the sidewall may have a protrusion on at least one region of an inner or outer peripheral surface thereof.

Further, a thickness of a region of the second reflective layer adjacent to the light emitting device may be greater than a thickness of a region of the second reflective layer adjacent to the sidewall.

Further, the region of the second reflective layer adjacent to the light emitting device may have the smallest inclination angle, while the region of the second reflective layer adjacent to the sidewall may have the largest inclination angle.

Further, the second reflective layer may have a curvature, with a second region located between the second reflective layer and the sidewall having a greater curvature than a first region adjacent to the light emitting device.

Further, the first region may be disposed between the second region and the light emitting device.

Further, the second reflective layer may have different radii of curvature in different regions, and the radius of curvature of a third region adjacent to the sidewall may be larger than that of the second region between the light emitting device and the sidewall.

Further, the second region may be disposed between the third region and the light emitting device.

Further, a surface area of the first reflective layer may be formed smaller than a surface area of the second reflective layer.

Further, at least one area of the first reflective layer may cover at least one area of the second reflective layer.

Further, the protective device is disposed on the base, and the second reflective layer may be arranged to cover one area of the protective device.

Further, the second reflective layer may include a plurality of second reflective layers, and at least one of the plurality of second reflective layers may be arranged spaced apart from each other along the inner peripheral surface of the sidewall.

Further, the second reflective layer may be arranged along the inner peripheral surface of the sidewall, and the second reflective layer may be arranged continuously.

Further, the second reflective layer may expose one area of the base.

Further, the second reflective layer may be disposed spaced apart from the light emitting device or the sidewall.

Further, the reflectivity of the second reflective layer may be higher than that of the first reflective layer at wavelengths of 300 nm or less.

Further, the second reflective layer may include aluminum.

In accordance with one embodiment of the present disclosure, there may be provided a light emitting apparatus including: a substrate; a light emitting device disposed on the substrate; a second light-transmitting layer disposed on the substrate and configured to transmit the light emitted from the light emitting device; a first reflective layer disposed between the substrate and the light emitting device; and a second reflective layer disposed on the substrate and configured to reflect light toward the second light-transmitting layer, wherein the substrate includes a base and a sidewall extending upward from an edge of the base, and the first reflective layer includes a plurality of first reflective layers spaced apart from each other in a horizontal direction.

Further, at least one of the plurality of first reflective layers may be disposed on one surface of the light emitting device.

Further, at least one of the plurality of first reflective layers may extend along an inner peripheral surface of the sidewall.

Further, the plurality of first reflective layers may form a peripheral surface along the inner peripheral surface.

Further, at least one of the plurality of first reflective layers may be spaced apart from the peripheral surface.

Further, the second reflective layer may be disposed between the plurality of first reflective layers.

Further, the second reflective layer may extend along the peripheral surface.

Further, an inner side of the second reflective layer may be connected to one of the plurality of first reflective layers.

Further, an outer side of the second reflective layer may be connected to another one of the plurality of first reflective layers.

Further, one region of the second reflective layer may be disposed on a region of the base where no first reflective layer is provided.

Further, a height of the second reflective layer may be substantially similar to a height of the first reflective layer.

Further, one region of the second base may not overlap with the second reflective layer.

Further, there may be provided the light emitting apparatus further including a protective device disposed on the base and disposed between the sidewall and the light emitting device, wherein the second reflective layer may cover at least a region of the protective device.

Further, at least one region of an inner peripheral surface or an outer peripheral surface of the sidewall may be provided with a protrusion.

Further, among regions of the second reflective layer, a region adjacent to the light emitting device may have the smallest inclination, and a region adjacent to the sidewall may have the largest inclination.

Further, the second reflective layer may have a curvature, and a second region of the second reflective layer located between the second reflective layer and the sidewall may have a greater curvature than a first region of the second reflective layer adjacent to the light emitting device.

Further, the first region may be disposed between the second region and the light emitting device.

Further, the second reflective layer may have different radii of curvature in different regions, and the radius of curvature of a third region adjacent to the sidewall may be larger than that of the second region between the light emitting device and the sidewall.

Further, the second region may be disposed between the third region and the light emitting device.

Further, a surface area of the first reflective layer may be formed smaller than a surface area of the second reflective layer.

Further, at least one area of the first reflective layer may cover at least one area of the second reflective layer.

Further, the second reflective layer may include a plurality of second reflective layers, and at least one of the plurality of second reflective layers may be arranged spaced apart from each other along the inner peripheral surface of the sidewall.

Further, the second reflective layer may be arranged along the inner peripheral surface of the sidewall, and the second reflective layer may be arranged continuously.

Further, the second reflective layer may expose one area of the base.

Further, the second reflective layer may be disposed spaced apart from the light emitting device or the sidewall.

Further, the reflectivity of the second reflective layer may be higher than that of the first reflective layer at wavelengths of 300 nm or less.

Further, the second reflective layer may include aluminum.

In accordance with one embodiment of the present disclosure, there may be provided a light emitting apparatus including: a substrate; a light emitting device disposed on the substrate; a second light-transmitting layer disposed on the substrate and configured to transmit the light emitted from the light emitting device; a first reflective layer disposed between the substrate and the light emitting device; and a second reflective layer disposed on the substrate and configured to reflect light toward the second light-transmitting layer, wherein the substrate includes a base and a sidewall extending upward from an edge of the base, the second reflective layer is disposed on a side surface of the light emitting device, and a third light-transmitting layer disposed between the second reflective layer and the light emitting device.

Further, the third light-transmitting layer may have a higher transmittance than the second reflective layer.

Further, a region of the second reflective layer may be spaced apart from the light emitting device.

Further, the third light-transmitting layer may increase in horizontal width from the light emitting device as a vertical distance from the base increases.

Further, the third light-transmitting layer may have an inclined surface such that the vertical distance from the base increases and a thickness of the third light-transmitting layer in a vertical direction decreases as a distance from the light emitting device increases.

Further, a height of the second reflective layer may decrease as the distance from the light emitting device decreases.

Further, there may be provided the light emitting apparatus further including a protective device disposed on the base so as to be disposed between the sidewall and the light emitting device, wherein the second reflective layer covers at least a portion of the protective device.

Further, at least one region of an inner peripheral surface or an outer peripheral surface of the sidewall may be provided with a protrusion.

Further, a region of the second reflective layer adjacent to the light emitting device may have a smaller thickness than a region of the second reflective layer adjacent to the sidewall.

Further, among regions of the second reflective layer, a region adjacent to the light emitting device may have the smallest inclination, and a region adjacent to the sidewall may have the largest inclination.

Further, the second reflective layer may have a curvature, and a second region of the second reflective layer located between the second reflective layer and the sidewall may have a greater curvature than a first region of the second reflective layer adjacent to the light emitting device.

Further, the first region may be disposed between the second region and the light emitting device.

Further, the second reflective layer may have different radii of curvature in different regions, and the radius of curvature of a third region adjacent to the sidewall may be larger than that of the second region between the light emitting device and the sidewall.

Further, the second region may be disposed between the third region and the light emitting device.

Further, a surface area of the first reflective layer may be formed smaller than a surface area of the second reflective layer.

Further, at least one area of the first reflective layer may cover at least one area of the second reflective layer.

Further, the protective device may be disposed on the base, and the second reflective layer may be arranged to cover at least a portion of the protective device.

Further, the second reflective layer may include a plurality of second reflective layers, and at least one of the plurality of second reflective layers may be arranged spaced apart from each other along the inner peripheral surface of the sidewall.

Further, the second reflective layer may be arranged along the inner peripheral surface of the sidewall, and the second reflective layer may be arranged continuously.

Further, the second reflective layer may expose one area of the base.

Further, the second reflective layer may be disposed spaced apart from the light emitting device or the sidewall.

Further, the reflectivity of the second reflective layer may be higher than that of the first reflective layer at wavelengths of 300 nm or less.

Further, the second reflective layer may include aluminum.

In accordance with one embodiment of the present disclosure, there may be provided a light emitting apparatus including: a substrate; a light emitting device and a protective device disposed on the substrate and configured to emit light; a second light-transmitting layer disposed on the substrate and configured to transmit the light emitted from the light emitting device; and a second reflective layer disposed on the substrate and configured to reflect light toward the second light-transmitting layer, wherein the substrate includes a base and a sidewall extending upward from an edge of the base, and the second reflective layer is disposed between the light emitting device and the protective device, horizontally spaced apart from the light emitting device and the protective device.

Further, a tangent of an angle formed by a region or vertex of a corner of the light emitting device and a contact point between the second reflective layer and the base may be less than 1.

Further, a height of the second reflective layer may be greater than the respective heights of the light emitting device and the protective device.

Further, the second reflective layer may have a convex shape facing upward.

Further, the first reflective layer disposed between the substrate and the light emitting device may be further included.

Further, at least one of the plurality of first reflective layers may be disposed on one surface of the light emitting device.

Further, at least one of the plurality of first reflective layers may extend along an inner peripheral surface of the sidewall.

Further, the plurality of first reflective layers may form a peripheral surface along the inner peripheral surface.

Further, at least one of the plurality of first reflective layers may be spaced apart from the peripheral surface.

Further, the second reflective layer may be disposed between the plurality of first reflective layers.

Further, the second reflective layer may extend along the peripheral surface.

Further, an inner side of the second reflective layer may be connected to any one of the plurality of first reflective layers.

Further, an outer side of the second reflective layer may be connected to another one of the plurality of first reflective layers.

Further, a portion of the second reflective layer may be disposed on a region of the base where the first reflective layer is not disposed.

Further, the height of the second reflective layer may be substantially similar to a height of the first reflective layer.

Further, the respective heights of the second reflective layer and the first reflective layer may be substantially similar.

Further, a portion of the base may not overlap with the second reflective layer.

Further, a surface area of the first reflective layer may be formed smaller than a surface area of the second reflective layer.

Further, at least one area of the first reflective layer may cover at least one area of the second reflective layer.

Further, the second reflective layer may include a plurality of second reflective layers, and at least one of the plurality of second reflective layers may be arranged spaced apart from each other along the inner peripheral surface of the sidewall.

Further, the second reflective layer may be arranged along the inner peripheral surface of the sidewall, and the second reflective layer may be arranged continuously.

Further, the second reflective layer may expose one area of the base.

Further, the reflectivity of the second reflective layer may be higher than that of the first reflective layer at wavelengths of 300 nm or less.

Further, the second reflective layer may include aluminum.

Further, at least one region of an inner peripheral surface or an outer peripheral surface of the sidewall may be provided with a protrusion.

In accordance with one embodiment of the present disclosure, there may be provided a light emitting apparatus including: a substrate; a light emitting device disposed on the substrate; a second light-transmitting layer disposed on the substrate and configured to transmit the light emitted from the light emitting device; a first reflective layer disposed between the substrate and the light emitting device; and a second reflective layer disposed on the substrate and configured to reflect light toward the second light-transmitting layer, wherein the substrate includes a base and a sidewall extending upward from an edge of the base, the second reflective layer is disposed on a side surface of the light emitting device, the light emitting device includes at least one of a device substrate, a first semiconductor layer, an active layer, and a second semiconductor layer.

Further, one of the device substrate, the first conductive semiconductor layer, the active layer, and the second conductive semiconductor layer may include the same material as the second reflective layer.

Further, a height of the device substrate may be greater than a height of the first reflective layer.

Further, a minimum thickness of the second reflective layer may be less than a thickness of the device substrate.

Further, a height of the second reflective layer may expose at least a region of a boundary between the device substrate and the first conductive semiconductor layer.

Further, the device substrate may be spaced apart from the second reflective layer.

Further, the device substrate may be disposed on at least one region of the first reflective layer.

Further, the light emitting device may further include a conductor.

Further, one region of the conductor may be embedded in one region of the second reflective layer.

Further, one region of the conductor may be exposed without being embedded in the second reflective layer.

Further, a height of the third light-transmitting layer may be equal to or greater than that of the device substrate.

Further, a thickness of a region of the second reflective layer adjacent to the light emitting device may be thinner than that of a region of the second reflective layer adjacent to the sidewall.

Further, among regions of the second reflective layer, a region adjacent to the light emitting device may have the smallest inclination, and a region adjacent to the sidewall may have the largest inclination.

Further, the second reflective layer may have a curvature, and a second region of the second reflective layer located between the second reflective layer and the sidewall may have a greater curvature than a first region of the second reflective layer adjacent to the light emitting device.

Further, the first region may be disposed between the second region and the light emitting device.

Further, the second reflective layer may have different radii of curvature in different regions, and the radius of curvature of a third region adjacent to the sidewall may be larger than that of the second region between the light emitting device and the sidewall.

Further, the second region may be disposed between the third region and the light emitting device.

Further, a surface area of the first reflective layer may be formed smaller than a surface area of the second reflective layer.

Further, at least one area of the first reflective layer may cover at least one area of the second reflective layer.

Further, the protective device may be disposed on the base, and the second reflective layer may be arranged to cover at least a portion of the protective device.

Further, the second reflective layer may include a plurality of second reflective layers, and at least one of the plurality of second reflective layers may be arranged spaced apart from each other along the inner peripheral surface of the sidewall.

Further, the second reflective layer may be arranged along the inner peripheral surface of the sidewall, and the second reflective layer may be arranged continuously.

Further, the second reflective layer may expose one area of the base.

Further, the second reflective layer may be disposed spaced apart from the light emitting device or the sidewall.

Further, the reflectivity of the second reflective layer may be higher than that of the first reflective layer at wavelengths of 300 nm or less.

Further, the second reflective layer may include aluminum.

Further, a third light-transmitting layer may be included between the second reflective layer and the light emitting device.

Further, the third light-transmitting layer may have a higher transmittance than the second reflective layer.

Further, a region of the second reflective layer may be spaced apart from the light emitting device.

Further, the third light-transmitting layer may increase in horizontal width from the light emitting device as a vertical distance from the base increases.

Further, the third light-transmitting layer may have an inclined surface such that the vertical distance from the base increases and a thickness of the third light-transmitting layer in a vertical direction decreases as a distance from the light emitting device increases.

Further, a height of the second reflective layer may decrease as the distance from the light emitting device decreases.

Further, there may be provided the light emitting apparatus further including a protective device disposed on the base so as to be disposed between the sidewall and the light emitting device, wherein the second reflective layer covers at least a region of the protective device.

Further, at least one region of an inner peripheral surface or an outer peripheral surface of the sidewall may be provided with a protrusion.

In accordance with one embodiment of the present disclosure, there may be provided a light emitting apparatus including: a substrate; a light emitting device disposed on the substrate and configured to emit light; a second light-transmitting layer disposed on the substrate and configured to transmit the light emitted from the light emitting device; a first reflective layer disposed between the substrate and the light emitting device; and a second reflective layer disposed on the substrate and configured to reflect light toward the second light-transmitting layer, wherein the substrate includes a base and a sidewall extending upward from an edge of the base, the second reflective layer is disposed on a side surface of the light emitting device, the light emitting device including at least one of a first light-transmitting layer, a first conductive semiconductor layer, an active layer, or a second conductive semiconductor layer.

Further, the first light-transmitting layer may be spaced apart from at least one of the first reflective layer and the second reflective layer.

Further, at least one of the first conductive semiconductor layer, the active layer, or the second conductive semiconductor layer may be disposed below a side surface of the second reflective layer in a vertical direction.

Further, the second reflective layer may be disposed on a region of a mesa area of the light emitting device.

Further, a region of the second reflective layer may be disposed on a region of the first light-transmitting layer.

Further, a transmittance of the first light-transmitting layer may be higher than that of the second reflective layer.

Further, the light-emitting device may further include a conductor.

Further, a region of the second reflective layer may be disposed on a region of the conductor.

Further, a region of the conductor may be exposed without being embedded in the second reflective layer.

Further, a third light-transmitting layer may be further disposed in a region of the light emitting device.

Further, a height of the third light-transmitting layer may be positioned lower than that of the first light-transmitting layer.

Further, the third light-transmitting layer may cover at least one region of one or more of the first conductive semiconductor layer, the active layer, and the second conductive semiconductor layer.

Further, the third light-transmitting layer may have a lower refractive index than the second light-transmitting layer.

Further, the third light-transmitting layer may increase in horizontal width from the light emitting device as a vertical distance from the base increases.

Further, a thickness of a region of the second reflective layer adjacent to the light emitting device may be thinner than that of a region of the second reflective layer adjacent to the sidewall.

Further, among regions of the second reflective layer, a region adjacent to the light emitting device may have the smallest inclination, and a region adjacent to the sidewall may have the largest inclination.

Further, the second reflective layer may have a curvature, and a second region of the second reflective layer located between the second reflective layer and the sidewall may have a greater curvature than a first region of the second reflective layer adjacent to the light emitting device.

Further, the second reflective layer may have different radii of curvature in different regions, and the radius of curvature of a third region adjacent to the sidewall may be larger than that of the second region between the light emitting device and the sidewall.

Further, a surface area of the first reflective layer may be formed smaller than a surface area of the second reflective layer.

Further, at least one area of the first reflective layer may cover at least one area of the second reflective layer.

Further, the protective device may be disposed on the base, and the second reflective layer may be arranged to cover at least a portion of the protective device.

Further, the second reflective layer may include a plurality of second reflective layers, and at least one of the plurality of second reflective layers may be arranged spaced apart from each other along the inner peripheral surface of the sidewall.

Further, the second reflective layer may be arranged along the inner peripheral surface of the sidewall, and the second reflective layer may be arranged continuously.

Further, the second reflective layer may expose one area of the base.

Further, the second reflective layer may be disposed spaced apart from the light emitting device or the sidewall.

Further, the reflectivity of the second reflective layer may be higher than that of the first reflective layer at wavelengths of 300 nm or less.

Further, the second reflective layer may include aluminum.

Further, the third light-transmitting layer may have a higher transmittance than the second reflective layer.

Further, a region of the second reflective layer may be spaced apart from the light emitting device.

Further, the third light-transmitting layer may increase in horizontal width from the light emitting device as a vertical distance from the base increases.

Further, the third light-transmitting layer may have an inclined surface such that the vertical distance from the base increases and a thickness of the third light-transmitting layer in a vertical direction decreases as a distance from the light emitting device increases.

Further, a height of the second reflective layer may decrease as the distance from the light emitting device decreases.

Further, there may be provided the light emitting apparatus further including a protective device disposed on the base so as to be disposed between the sidewall and the light emitting device, wherein the second reflective layer covers at least a portion of the protective device.

Further, at least one region of an inner peripheral surface or an outer peripheral surface of the sidewall may be provided with a protrusion.

[Explanation of Symbols]

| | |
|---|---|
| 1: light emitting module | 100: substrate |
| 110: base | 120: sidewall |
| 121: protrusion | 200: light emitting device |
| 210: device substrate | 220: first conductive semiconductor |
| | layer |
| 230: active layer | 240: second conductive semiconductor |
| | layer |
| 250: first light-transmitting | 300: second light-transmitting layer |
| layer | |
| 400: semiconductor device | 500: first reflective layer |
| 600: second reflective layer | 700: third light-transmitting layer |
| 800: conductor | |

1. A light emitting apparatus, comprising:
a substrate;
a light emitting device disposed on the substrate;
a second light-transmitting layer disposed on the substrate so that light generated from the light emitting device is transmitted therethrough;
a first reflective layer disposed between the substrate and the light emitting device; and
a second reflective layer disposed on the substrate and configured to reflect light toward the second light-transmitting layer,
wherein the second reflective layer includes 20 wt % to 70 wt % of aluminum and 10 wt % to 60 wt % of oxygen.

2. The light emitting apparatus of claim 1, wherein the second reflective layer further includes silicon and carbon, and a content of the carbon is greater than a content of the silicon.

3. The light emitting apparatus of claim 1, wherein the substrate includes:
a base supporting the light emitting device, the first reflective layer, and the second reflective layer; and
a sidewall extending upward from the base at an edge of the base, and
wherein the second reflective layer is disposed between the sidewall and the light emitting device.

4. The light emitting apparatus of claim 3, wherein the second reflective layer is formed in plural, and the plurality of second reflective layers are disposed to be spaced apart from each other along an inner region of the sidewall.

5. The light emitting apparatus of claim 3, further comprising a plurality of protrusions formed in an inner region of the sidewall.

6. The light emitting apparatus of claim 3, wherein a thickness of the second reflective layer increases toward the sidewall.

7. The light emitting apparatus of claim 6, wherein a surface of the second reflective layer includes a region that is concave downward.

8. The light emitting apparatus of claim 3, wherein a thickness of the second reflective layer decreases toward the sidewall.

9. The light emitting apparatus of claim 3, further comprising:
a protective device disposed on the base so as to be disposed between the sidewall and the light emitting device,
wherein the second reflective layer covers at least one region of the protective device.

10. The light emitting apparatus of claim 1, wherein the second reflective layer and the light emitting device are spaced apart from each other.

11. The light emitting apparatus of claim 1, wherein the light emitting device is disposed inside the first reflective layer when viewed from one region.

12. The light emitting apparatus of claim 1, wherein the second reflective layer includes at least one of alumina (Al₂O₃) or barium sulfate (BaSO₄).

13. The light emitting apparatus of claim 1, wherein the second reflective layer further includes one or more fillers to refract light, and
wherein an average of lengths of long sides of the one or more fillers is 100 nm to 2 μm.

14. The light emitting apparatus of claim 1, further comprising:
a third light-transmitting layer disposed on at least one region of the light emitting device.

15. The light emitting apparatus of claim 1, wherein the first reflective layer and the second reflective layer are formed to differ from each other in at least one of reflectance, thermal conductivity, or thermal expansion coefficient.

16. The light emitting apparatus of claim 1, wherein the first reflective layer is formed in plural and spaced apart from each other in a horizontal direction,
the light emitting device is disposed above one of the plurality of first reflective layers spaced apart from each other in the horizontal direction, and
the second reflective layer is disposed between the plurality of first reflective layers.

17. A light emitting apparatus, comprising:
a substrate;
a light emitting device disposed on the substrate;
a second light-transmitting layer disposed on the substrate so that light generated from the light emitting device is transmitted therethrough;
a first reflective layer disposed between the substrate and the light emitting device; and
a second reflective layer disposed on the substrate and configured to reflect light toward the second light-transmitting layer,
wherein the light emitting device includes:
a device substrate stacked on the first reflective layer;
a first conductive semiconductor layer stacked on the device substrate;
an active layer stacked on the first conductive semiconductor layer; and
a second conductive semiconductor layer stacked on the active layer.

18. The light emitting apparatus of claim 17, wherein the substrate includes:
a base on which the light emitting device disposed, the first reflective layer, and the second reflective layer; and
a sidewall extending upward from the base at an edge of the base,
wherein the first reflective layer is disposed a position where at least one region thereof faces the light emitting device and another region opposite the at least one region faces the sidewall, and
wherein the at least one region of the first reflective layer is disposed below a region between the device substrate and the first conductive semiconductor layer.

19. A light emitting apparatus, comprising:
a substrate;
a light emitting device disposed on the substrate and configured to generate light;
a second light-transmitting layer disposed on the substrate so that light generated from the light emitting device is transmitted therethrough;
a first reflective layer having at least one region disposed between the substrate and the light emitting device; and
a second reflective layer disposed on the substrate and configured to reflect light toward the second light-transmitting layer,
wherein the light emitting device includes:
a first conductive semiconductor layer electrically connected to the substrate;
an active layer stacked on the first conductive semiconductor layer;
a second conductive semiconductor layer stacked on the active layer and electrically connected to the substrate; and
a first light-transmitting layer stacked on the second conductive semiconductor layer.

20. The light emitting apparatus of claim 19, wherein a region between the second conductive semiconductor layer and the first light-transmitting layer is disposed below a surface of the second reflective layer.
